(19) United States
(12) Patent Application Publication
(10) Pub. No.: US 2014/0021464 A1
(43) Pub. Date: Jan. 23, 2014

(54) Yttrium-doped Indium Oxide Transparent Conductive Thin-Film Transistor and Method for Making Same

(71) Applicants: Chu-Chi Ting, Chiayi County (TW); Meng-Kun Tsai, Chiayi County (TW); Hsin-Yun Fan, Chiayi County (TW)

(72) Inventors: Chu-Chi Ting, Chiayi County (TW); Meng-Kun Tsai, Chiayi County (TW); Hsin-Yun Fan, Chiayi County (TW)

(73) Assignee: National Chung Cheng University, Chiayi County (TW)

(21) Appl. No.: 13/550,653

(22) Filed: Jul. 17, 2012

(51) Int. Cl. H01L 29/786; H01L 29/66

(52) U.S. Cl. CPC H01L 29/7869; H01L 29/66742
USPC 257/43; 438/104

(57) ABSTRACT

The present invention provides a transistor and method for making the same. The transistor has an yttrium-doped indium oxide transparent conductive thin-film which is so fabricated with the method to reduce the formation of oxygen vacancies, suppress carrier concentration effectively, and decrease maximum defect density and thus suitable to be applied to the transistor.

### BACKGROUND OF THE INVENTION

1. Field of the Invention

The present invention relates to an oxide transparent conductive thin-film transistor and method for making same, and particularly to an yttrium-doped indium oxide transparent conductive thin-film transistor and method for making same.

2. Description of the Prior Arts

People in the 21st century pursue high quality and user-friendliness of various life appliances. Displays have been developed from traditional cathode radiation tubes (CRT) to flat panel displays (FPD), so thin film transistor liquid crystal displays (TFT-LCDs) emerge at demand. With the advance of technology and science, the development of transistors is gradually mature, and Taiwan is already the world's second largest TFT-LCDs maker and shows remarkable progress in both technologies and developments of TFT-LCDs. The application fields of TFT-LCDs include desktop monitors, laptops, LCD televisions, cell phones, automobile monitors, digital cameras, video cameras, and handheld devices. Hence, the TFT-LCDs have already become one of the most important parts in our life.

As mentioned in Weimer, P. K. Proc. IRE 50(6), 1462-1469 (1962), TFT was proposed by Weimer in 1962. The semiconductor layer of the TFT was cadmium sulfide (CdS), wherein SiO₂ was used as the gate insulation layer of the TFT and gold was used as drain and source of the TFT. The thin films were all formed by vapor deposition.

Recently, TFTs under development are mainly classified into inorganic type and organic type. Most of the inorganic TFTs use hydrogenated amorphous silicon (a-Si:H) as the major material; however, conventional amorphous silicon thin film transistors (α-Si TFT) using amorphous silicon as the material of the active layer have gradually failed to meet market requirements due to the limit of the carrier mobility (less than 1 cm²/V-s) of the α-Si TFT. Besides, as low temperature poly-Si TFT (LTPS-TFT) was proposed in the late 1990s, LTPS-TFTs have become the main trend in the technical development of the next generation due to many advantages, including: presenting vivid and sharp color resolution by higher carrier mobility and simultaneously meeting the requirements of being thinner and lighter, lower power consumption, higher response rate and wider viewing angles, and providing portable products and reducing costs by hiding circuits of LCD modules in a glass substrate.

The material for fabricating most of the electronic devices nowadays including integrated circuit, transistor, diode, solar cell, etc is inorganic silicon. As shown in Table 1, because the mobility of the inorganic material is more than three orders of magnitude larger than the mobility of the organic material, organic TFT does not perform as well as inorganic TFT under high frequency. Except liquid crystal itself, the major material for fabricating the driving circuit of the TFT is still silicon. Both the fabricating processes of integrated circuit and of the driving circuit of liquid crystal display need a considerably high temperature, so the silica substrates or the glass substrates used in the fabricating processes should be high-temperature resistant, which makes those substrates non flexible. However, if the active layers of the electronic devices can be replaced by organic semiconductor material, the flexible plastic substrates can be used to replace the aforementioned substrates because the deposition of the organic material can be operated at near room temperature, as shown in Table 2, which compares data of organic TFT and inorganic TFT. Because organic electronic devices have advantages including capability of being fabricated as flexible electronics, capability of being fabricated by a low-temperature processing, being lightweight and capability of being deposited on plastic substrates, organic electronic devices become a new trend of the future.

TABLE 1

| | Material | Mobility(μp) | |
|---|---|---|---|
| Inorganic | Ge | 1900 | (cm²v⁻¹s⁻¹) |
| Semiconductor | Si | 450 | (cm²v⁻¹s⁻¹) |
| | GaAs | 400 | (cm²v⁻¹s⁻¹) |
| | InP | 150 | (cm²v⁻¹s⁻¹) |
| Organic | Polyacetylene | 0.0001 | (cm²v⁻¹s⁻¹) |
| Semiconductor | α-W-hexathiophene | 0.03 | (cm²v⁻¹s⁻¹) |
| | C 60 | 0.3 | (cm²v⁻¹s⁻¹) |
| | Pentacene | 1.5 | (cm²v⁻¹s⁻¹) |

TABLE 2

| | | | Process | Fabrication |
|---|---|---|---|---|
| | material | process | temperature | cost |
| TFT | Amorphous or | Semi- | Higher | costly |
| | poly-silicon | conductor | temperature | |
| | | process | (200~400° C.) | |
| OTFT | small molecular, | Printing | Lower | cheaper |
| | polymer, or | process | temperature | |
| | organic metal | | (<100° C.) | |
| | complex | | | |

Cell phone screens and MP3 panels are still the major markets of OLED applications. The cell phone screens and MP3 panels both adopt passive matrix/organic light emitting diode (PMOLED) panels. With regard to active matrix/organic light emitting diode (AMOLED), the major driving force of the market is from the high-level mobile phones and large-size applications.

In the aspect of display performance, AMOLED has advantages including: higher response rate, higher contrast ratio and wider viewing angle. Moreover, AMOLED has a self-illumination property, which avoids using a backlight plate, so AMOLED is thinner and more energy saving than TFT. Currently, the power consumption of AMOLED panel is about 60% of the power consumption of TFT LCD, which is to be further lowered by future technical advancement. Besides, AMOLED without using a backlight plate can save the cost of backlight plate, while the backlight module of TFT LCD accounts for about 30% to 40% of total cost of TFT LCD. The result will bring fundamental changes to the panel industry.

As mentioned in Ryu, M. K. et al. SID 09 188 (2009) and Kim, T. S. et al. Current Applied Physics 11, 1253-1256 (2011), in recent years, researches in oxide transistors gradually applied to AMOLED are remarkable. An AMOLED screen, which can be folded one hundred thousand times while without having any creases, is developed successfully recently and next year, a quantity production of the AMOLED screen is anticipated.

As for transparent conductive oxide (TCO), the TCO has a good electrical conductivity and a good transmittancy. The TCO is mainly composed of metal oxide. The TCO is widely used in flat panel displays (FPD), touch panels, transmitting glass for architectural resource, and transmitting and conductive electrodes. Moreover, TCO is also an important thin film layer of a solar cell. The commonly used TCO materials include: ITO, In₂O₃, SnO₂, ZnO, CdO, AZO, IZO, etc.

In general, as the electrical conductivity increases, the transmittance decreases, as well as the other way around. In the range of visible light, a good TCO has a transmittance over 80% and a specific resistance lower than 1×10⁻⁴ Ωcm. TCO materials can be classified into two types: pure metal thin films and TCO.

1. Pure Metal Thin Films

The metal includes Au, Ag, Pt, Cu, Al, Cr, Pd and Rh. A thin film with a thickness less than 10 nm to some extent has drawbacks of visible light transmittance including: large absorbance of light, low hardness and low stability.

2. TCO

The TCO includes any oxides, nitrides and fluorides with transparent and electrically conductive properties. With reference to Minami, T. SEMICONDUCTOR SCIENCE AND TECHNOLOGY 20, S35-S44 (2005), transparent oxide semiconductor and transparent conductive oxide of electrode material are tabulated in Table 3.

a. Oxides and nitrides: In₂O₃, SnO₂, ZnO, CdO, TiN.

b. Doped with oxides: In₂O₃:Sn (ITO), ZnO:In (IZO), ZnO:Ga (GZO), ZnO:Al (AZO), SnO₂:F, TiO₂:Ta.

c. Mixed oxides: In₂O₃—ZnO, CdIn₂O₄, Cd₂SnO₄, Zn₂SnO₄

TABLE 3

| Materials | Dopant or compound |
|---|---|
| SnO₂ | Sb, F, As, Nb, Ta |
| In₂O₃ | Sn, Ge, Mo, F, Ti, Zr, Hf, Nb, Ta, W, Te |
| ZnO | Al, Ga, B, In, Y, Sc, F, V, Si, Ge, Ti, Zr, Hf |
| CdO | In, Sn |
| ZnO—SnO₂ | Zn₂SnO₄, ZnSnO₃ |
| ZnO—In₂O₃ | Zn₂In₂O₅, Zn₃In₂O₆ |
| In₂O₃—SnO₂ | In₄Sn₃O₁₂ |
| CdO—SnO₂ | Cd₂SnO₄, CdSnO₃ |
| CdO—In₂O₃ | CdIn₂O₄ |
| MgIn₂O₄ | |
| GaInO₃, (Ga, In)₂O₃ | Sn, Ge |
| CdSb₂O₆ | Y |
| ZnO—In₂O₃—SnO₂ | Zn₂In₂O₅—In₄Sn₃O₁₂ |
| CdO—In₂O₃—SnO₂ | CdIn₂O₄—Cd₂SnO₄ |
| ZnO—CdO—In₂O₃—SnO₂ | |

TCO has been used in many fields including touch panel, AMLCD, OLED dye-sensitized solar cell (DSSC) and solar cell, and TCO is more appropriate to be formed on flexible substrates to produce flexible electronic products.

Indium oxide (In₂O₃) is a direct wide band gap semiconductor material wherein the energy gap (Eg) of the indium oxide is 3.6 eV. The indium oxide has a high electrical conductivity and has a property of high visible light transmittance, so indium oxide is widely used in many electronic devices such as solar cells and thin-film resistors.

As mentioned in Bing, L. S. et al. Chinese J. Struct. Chem. 28, 360-364 (2009) and Tomita, T. et al. APPLIED PHYSICS LETTERS 87, 051911 (2005), the lattice structure of indium oxide is cubic bixbyite. The appearance of indium oxide is yellow solid and the indium oxide exhibits a melting point of 1910° C., density of 7.19 g/cm³, molar mass of 277.6 g, lattice constant of 10.12 Å, and space group Ia3, which is like a fluorite structure. Each unit lattice of In₂O₃ has 80 atoms wherein eight indium ions occupy b-sites, 24 indium ions occupy d-sites and the rest of the 48 oxygen ions occupy e-sites.

Fluorite face-centered cubic has 3/4 interstitial sites of tetrahedron filled with O²⁻ while In³⁺ fill the sites of the face-centered cubic. As shown in FIG. 1 and FIG. 2, in the Fluorite face-centered cubic structure, the distances from an In³⁺ occupying a b-site to the six oxygen ions surrounding that b-site are equal (2.19 Å) while the distances from an In³⁺ occupying a d-site to the six oxygen ions surrounding that d-site are not equal (2.12, 2.19 and 2.21 Å).

TCO TFTs mainly include indium oxide thin-film transistors, amorphous oxide semiconductors (AOSs) and transition elements-doped indium oxide thin-film transistors.

The electric properties of indium oxide thin film include many properties. Indium oxide exhibits metal property, semi-conductive property and insulator property by chemical stoichiometry of the material and by the defects of the material. Indium oxide is an insulator in terms of the chemical structure while indium oxide having oxygen vacancies exhibits N-type semiconductor form and further exhibits metal property with increasing oxygen vacancies.

Many processes including magnetron sputtering, atomic layer deposition (ALD), ion beam assisted deposition (IAD), pulsed laser deposition (PLD), ion beam assisted evaporation (IBAE), thermal evaporation and sol-gel process can be used to fabricate indium oxide thin films.

In 2010, Zhang, H. Z. Solid-State Electronics 54, 479-483 (2010), published by Qing Wan et al., disclosed that they used magnetron sputtering to fabricate an indium oxide TFT. They sputtered indium oxide on an N-type silica substrate having a SiO₂ dielectric layer and improved the TFT property by changing deposition pressures. They found that the TFT exhibited better property when the deposition pressure was decreased. From atomic force microscopy (AFM), they found that when the deposition pressure was low, the surface roughness of the TFT was decreased as well. Hence, the TFT exhibited better properties of field-effect mobility (μₛₐₜ) of 31.6 cm²V⁻¹s⁻¹, IDS on/off ratio (I_{on/off}) of 10⁷ and threshold voltage (V_{T}) of 7.8 V.

In 2008, Antonio Facchetti et al. and Tobin J. Marks et al. used sol-gel process to fabricate an indium oxide TFT, as mentioned in Kim, H. S. et al. J. AM. CHEM. SOC. 130, 12580-12581 (2008). They obtained an indium oxide TFT with better performance mainly by changing the dielectric material to make the dielectric layer have a high dielectric constant and by changing the concentration of the active layer material. The TFT exhibited properties of field-effect mobility ratio (μₛₐₜ) of 43.7 cm²V⁻¹s⁻¹, I_{DS on/off} ratio (I_{on/off}) of 10⁶, threshold voltage (V_{T}) of 2.2V and subthreshold swing (S.S.) of 0.3.

In 2011, Han, S. Y. et al. J. Am. Chem. Soc. 133, 5166-5169 (2011), published by Chih-hung Chang et al., disclosed that they used sol-gel process at low temperature to fabricate indium oxide TFTs, and the parameters are tabulated in Table 4. The aforementioned publications have disclosed that sintering indium oxide to form the thin film should be operated at a high temperature. However, in order to fabricate indium oxide TFTs on flexible substrates, lowering process temperature is necessary, so the cited paper disclosed that a cost-effective sol-gel process was used and the indium oxide TFTs were sintered under atmosphere or O₂/O₃ wherein the temperature was between 200° C. and 600° C.

TABLE 4

| | | Temperature | | | | | | | |
|---|---|---|---|---|---|---|---|---|---|
| Environment | | 200° C. | 230° C. | 250° C. | 280° C. | 300° C. | 400° C. | 500° C. | 600° C. |
| Air | μ (cm²V⁻¹s⁻¹) | | | | | 3.8 | 17.43 | 55.26 | 37.75 |
| | I_{On/Off} | | | | | 10⁶ | 10⁶ | 10⁷ | 10⁵ |
| O₂/O₃ | μ (cm²V⁻¹s⁻¹) | 0.85 | 1.05 | 11.18 | 22.14 | 16.76 | | | |
| | I_{On/Off} | 10⁵ | 10⁶ | 10⁶ | 10⁶ | 10⁵ | | | |

As shown in Table 4, the best field-effect mobility of 55.26 cm²V⁻¹s⁻¹ was obtained when the indium oxide TFT was sintered under atmosphere at 500° C., and the I _{On/Off} of the TFT was 10⁷. The indium oxide TFT sintered under O₂/O₃ exhibited the best field-effect mobility of 22.14 cm²V⁻¹s⁻¹ at 280° C., and the I_{On/Off} of the TFT was 10⁶. The TFT sintered at 230° C. exhibited field-effect mobility of 1.05 cm²V⁻¹s⁻¹ and I _{On/Off} of 10⁶, which was already adapted for applications on TFT LCDs. The paper showed that indium oxide TFTs with high performance could be fabricated at a temperature below 250° C., which was a big boost to the application of indium oxide TFTs to flexible substrates and to the developments of flexible electronic devices.

From the aforementioned publications, the parameters including types of dielectric layer, active layer material, concentration, sintering temperature, pressure and atmosphere all can change TFT properties.

Moreover, amorphous oxide semiconductors (AOSs) are noteworthy recently. AOS transistors have advantages such as high transmittance, good stability, and high mobility, and can be fabricated by low-temperature process. All the advantages are appropriate for fabrication of transistors.

The conduction bands of AOSs are driven by metal ions having large radiuses in the ns orbital such as In³⁺, Ga³⁺, and Zn²⁺. Common metal oxides are polycrystalline structures, but the grain boundaries do not affect the stability and the consistence of the whole device. In order to improve the stability and the consistence of the whole device, metal ions such as In³⁺, Ga³⁺, and Zn²⁺ are added because those metal ions have large radiuses. The vacant s-orbital is so large in space such that the s-orbital of the adjacent cation is possible to overlap with the oxides, and a more effective transmittance of electrons is obtained due to the large overlapping area caused by the large radiuses of metal ions. As shown in Nomura, K. et al. NATURE 4332, 25 (2004), it discloses a structure of a-IGZO transistor, characterized in that the device was fabricated on a flexible PET substrate and Y₂O₃ was used as the dielectric layer to fabricate the full transparent TFT. The TFT exhibits field-effect mobility (μₛₐₜ) of 6-9 cm²V⁻¹s⁻¹, I_{DS on/off ratio} (I_{on/off}) of 10³ and the threshold voltage (V_{T}) of 1.6V.

On the other hand, in 2010, Kim, D. N. et al. APPLIED PHYSICS LETTERS 97, 192105 (2010) mentioned that sol-gel process was used to dope transition metal La into ITO system. Compared to the electronegativity difference between In/O and the electronegativity difference between Zn/O, the electronegativity difference between La and O is the largest, wherein the electronegativity of La is 1.1, the electronegativity of In is 1.7, the electronegativity of Zn is 1.8 and the electronegativity of O is 3.5. As a result, La—O has a strong bond and doping La effectively binds oxygen, thus suppressing the formation of oxygen vacancies and decreasing the carrier concentration. When [La]/([In]+[Zn]) was 0.05, a minimum S and a minimum threshold voltage shift existed. A maximum interface trap state equation of Nsmax—[Slog(e)/(kT/q)−1]Ci/q was used to calculate a minimum interface defect of the active layer/dielectric layer interface at the doping concentration of [La]/([In]+[Zn]) of 0.05. Besides, from the result of AFM, the LIZO (0.5:5:5) thin film had a minimum surface roughness of 0.295 nm while the surface roughness of LIZO (2:5:5) thin film increased to 6.802 nm, and the increasing roughness was caused by lattice mismatch attributed to ionic radius of La³⁺(r=0.106 nm) being much larger than the ionic radius of In³⁺ (r=0.079 nm) and the ionic radius of Zn²⁺ (r=0.074 nm). The LIZO (0.5:5:5) transistor mentioned in the paper exhibited best properties of μFE of 2.64 cm²/Vs, subthreshold voltage swing of 1.45 V/dec, Vth of 7.86 V and I_{on/off ratio} of 10⁶.

In 2010, as mentioned in Choi, Y. et al. APPLIED PHYSICS LETTERS 97, 162102 (2010), sol-gel process was used to dope transition element Sc into IZO system. Because Sc is easily ionized because of having a low standard electrode potential, Sc will form a strong bond with O²⁻, thus suppressing the formation of oxygen vacancies and results in increasing electrical resistivity with increasing doping ratio of Sc. Besides, with doping ratios of Sc increasing from 4% to 32%, optical energy gap increased from 3.35 eV to 3.70 eV and the transmittance over the wavelength range 300-700 nm was over 90%. TFT with the best properties was with a doping ratio of Sc of 14%, and the TFT exhibited μFE of 2.06 cm²/Vs, SS of 0.93 V/dec, Vth of 4.31 V, and I_{on/off ratio} of 8.02×10⁶.

In 2010, as mentioned in Shin, H. S. et al. Japanese Journal of Applied Physics 49, 03CB01-1 (2010), sol-gel process was used to dope yttrium into yttrium-doped indium zinc oxide (YIZO) thin film transistors. Because yttrium is also easily ionized because of having a low standard electrode potential, yttrium will form a strong bond with O²⁻, thus suppressing the formation of oxygen vacancies and resulting in reduced carrier concentration and leading the mobility to decrease with increased concentration of yttrium. The TFT properties were improved through changing the concentrations of yttrium and changing the sintering temperature. TFT had the best properties with a doping concentration of yttrium of 15%, and the TFT exhibited μFE of 1.12 cm²/Vs, SS of 1.03 V/dec, Vth of 0.54 V, and I_{on/off ratio} of 8.02×10⁶.

As mentioned in Kagan, C. R. et al. THIN-FILM TRANSISTORS, a transparent conductive thin-film transistor is mainly composed of a substrate, a dielectric layer, an active layer and electrodes. The device structure can be classified into top contact and bottom contact.

The working principle of the TFT is similar with the MOSFET. As a result, the principle of the MOSFET would be explained to illustrate the working principle of the TFT. Metal electrodes of a TFT include the gate, the source and the drain e and the function of the metal electrodes is controlling the conduction of the channel of the TFT device by changing the voltage.

When applying a gate voltage to reach a certain voltage, a channel is formed and the drain and the source are electrically connected. The certain voltage is called the threshold voltage. Besides, the current increases with the increasing voltage, and the TFT device is defined to be in the linear region. The TFT device will be in a stable state until the channel is pinched-off, and if the voltage further increases, the current will show a stable and a saturated state, and the TFT device is defined to be in the saturate region, as shown in FIG. 3. The equation of the linear region is:

$$\begin{matrix}{I}_{D} = μ {C}_{i} \frac{W}{L} [ ( {V}_{G} - {V}_{t} ) {V}_{D} - \frac{{V}_{D}^{2}}{2} ] & {V}_{D} \leq {V}_{G} - {V}_{t}\end{matrix} \qquad ( Eq . 2 - 1 )$$

The equation of the saturate region is:

$$\begin{matrix}{I}_{D} = μ {C}_{i} \frac{W}{L} \frac{{( {V}_{G} - {V}_{t} )}^{2}}{2} & {V}_{D} > {V}_{G} - {V}_{t}\end{matrix} \qquad ( Eq . 2 - 2 )$$

Where μ is carrier mobility, V, is the threshold voltage, W is the width of the channel of the TFT, L is the length of the channel of the TFT, Ci is the capacitance per unit area of the insulator layer and V_{G} is the gate voltage.

As mentioned in Kagan, C. R. et al. THIN-FILM TRANSISTORS, TFT involves many important parameters. To determine the quality of the TFT, a number of important properties are taken into account. As shown in Table 5, the important properties include carrier mobility (μ), threshold voltage (Vth), I_{DS on/off ratio} (I_{on/off}), subthreshold swing and maximum defect density (N_{SS}^{max}).

TABLE 5

| TFT performance | Dominant factor |
|---|---|
| On-current | W/L |
| | Drift mobility |
| | Interface states (a-Si:H/SiNₓ) |
| | Ohmic contact |
| | Gap state density |
| | Back interface states |
| Off-current | W/L |
| | Fermi level (a-Si:H) |
| | Interface (a-Si:H/SiNₓ) states |
| | Back surface charge |
| | n⁺ contact (n⁺ a-Si:H) |
| | Band gap |
| Field-effect mobility | Width of band tails |
| | Interface states (SiNₓ/a-Si:H) |
| Gate voltage swing | Gap states (defect states) |
| | Interface states |

About mobility:

The definition of mobility:

An n-type semiconductor with an evenly distributed concentration under a state of thermal equilibrium is studied. According to the theory of the energy distribution, each degree of freedom contributes energy kT/2 to the average energy of an electron, and the electron of the semiconductor has three degrees of freedom, so the kinetic energy of the electron is:

$$\frac{1}{2} {m}_{n} {V}_{th}^{2} = \frac{3}{2} kl \qquad ( Eq . 2 - 3 )$$

Wherein mₙ is the equivalent mass of the electron in material, Vth is the thermal velocity, k is Boltzmann's constant, and T is the Kelvin temperature.

When an electric field is applied to the semiconductor, a force −qE affects the electrons, and the electrons will collide with atoms. During each collision, the electrons will be accelerated in an opposite direction to the electric field, so the electrons obtain an additional velocity, which is called drift velocity, that is, the electron motion is caused by random thermal motion and drift motion. During a mean free time between collisions of conduction electrons, the increasing amount of momentum of the electrons caused by electric field is:

−qEτ_{c}=mₙνₙ (Eq. 2-4)

A correlation between electric field and drift velocity is obtained by transposing terms of equation 2-4, and the correlation is shown as

$$\begin{matrix}{v}_{n} = ( \frac{q {τ}_{c}}{{m}_{n}} ) E & ( Eq . 2 - 5 ) \\ {v}_{n} = - {μ}_{n} E & ( Eq . 2 - 6 )\end{matrix}$$

wherein τ_{c} is the mean free time between collisions of conduction electrons, and the constant of the drift velocity to the electric field is defined as electron mobility.

Hole mobility can be obtained with the same derivation as mentioned above. And the equation of hole mobility is:

$$\begin{matrix}{v}_{p} = - ( \frac{q {τ}_{c}}{{m}_{p}} ) E & ( Eq . 2 - 7 ) \\ {v}_{p} = - {μ}_{p} E & ( Eq . 2 - 8 )\end{matrix}$$

Wherein the unit of mobility is:

$$\frac{cm / s}{V / cm} = {cm}^{2} / Vs$$

That is, mobility is defined as the magnitude of the drift velocity per unit electric field.

The linear-region mobility of TFT is calculated as:

$$\begin{matrix}{I}_{D} = μ {C}_{i} \frac{W}{L} [ ( {V}_{G} - {V}_{t} ) {V}_{D} - \frac{{V}_{D}^{2}}{2} ] & {V}_{D} \leq {V}_{G} - {V}_{t}\end{matrix} \\ {g}_{m} = \frac{\partial {I}_{D}}{\partial {V}_{G}} = \frac{W}{L} μ {C}_{ox} {V}_{D} \qquad ( Eq . 2 - 9 )$$

As a result, the linear-region mobility is obtained.

$$μ = \frac{L}{{WC}_{ox} {V}_{D}} {g}_{m} \qquad ( Eq . 2 - 10 )$$

The saturation region mobility of TFT is calculated as:

$$\begin{matrix}\begin{matrix}{I}_{D} = μ {C}_{i} \frac{W}{L} \frac{{( {V}_{G} - {V}_{i} )}^{2}}{2} & {V}_{D} \geq {V}_{G} - {V}_{t}\end{matrix} & ( Eq . 2 - 11 ) \\ \frac{\partial \sqrt{{I}_{D}}}{\partial {V}_{G}} = \sqrt{\frac{{WC}_{ox}}{2 L}} μ & ( Eq . 2 - 12 )\end{matrix}$$

As a result, the saturation region mobility is obtained.

$$μ = \sqrt{\frac{2 L}{{WC}_{ox}}} \times \frac{\partial \sqrt{{I}_{D}}}{\partial {V}_{G}} \qquad ( Eq . 2 - 13 )$$

About threshold voltage:

In MOSFET, strong inversion cannot take place when the gate voltage is less than the threshold voltage, and the threshold voltage represents the gate voltage required for the TFT's shift from off-state to on-state. If Vₜₕ is closer to 0, a lower voltage is required to operate the TFT device.

From the linear regression of the I_{D}^{1/2} versus V_{G} curve at the current in saturation being virtually independent of threshold voltage, carrier mobility can be obtained from the slope of the regression line and the X intercept of the regression line determines the threshold voltage (Vₜₕ).

About I_{On/Off ratio}:

On-current represents the transistor is in on-state while off-current represents the transistor is in off-state. A low off current indicates a low leakage current. An I_{On/Off ratio} is important for transistors.

About subthreshold swing:

Subthreshold swing is an important parameter of transistors. As a transistor operates, the transistor must be switched rapidly; hence, the current must increase quickly when a small gate bias is applied to the transistor. The subthreshold swing is defined as an applied gate voltage required for increasing one order of magnitude of current, so a good transistor must have a subthreshold swing as low as possible, that is, the transistor only needs a low voltage to shift from off-state to on-state.

The equation of the subthreshold swing is:

$$S = \frac{d {V}_{G}}{d ( log {I}_{D} )} \qquad ( Eq . 2 - 14 )$$

About maximum defect density (N_{SS}^{max}):

As mentioned in Nayak, P. K. et al. APPLIED PHYSICS LETTERS 95, 193503 (2009), maximum defect density of the active layer/dielectric layer interface can be calculated from S.S value of equation 2-11, and the maximum defect density can be shown as

$${N}_{SS}^{max} = ( \frac{S log ( e )}{kT / q} - 1 ) \frac{{C}_{i}}{q} \qquad ( Eq . 2 - 15 )$$

### SUMMARY OF THE INVENTION

Given that the market demand for the technique for oxide applied to thin-film transistors (TFT), the present invention provides a transistor and method for making the same to meet the market demand. The material of the active layer of the transistor is an oxide material. An yttrium-doped indium oxide (YIO) thin film is fabricated by doping yttrium into indium oxide system and sol-gel process is used to coat the YIO thin film on a silica/silicon substrate uniformly. The YIO thin film exhibits a crystalline state after being sintered at a high temperature. The process is under non-vacuum atmosphere, which reduces production cost and production time notably. Moreover, based on the electronegativity and the standard electrode potential (SEP), the present invention uses the yttrium as the dopant into indium oxide system to suppress carrier concentration. As a result, the present invention provides an yttrium-doped indium oxide transparent conductive thin-film transistor and method for making same.

Other objectives, advantages and novel features of the invention will become more apparent from the following detailed description when taken in conjunction with the accompanying drawings.

### BRIEF DESCRIPTION OF THE DRAWINGS

FIG. 1 is a schematic diagram of the structure of indium oxide;

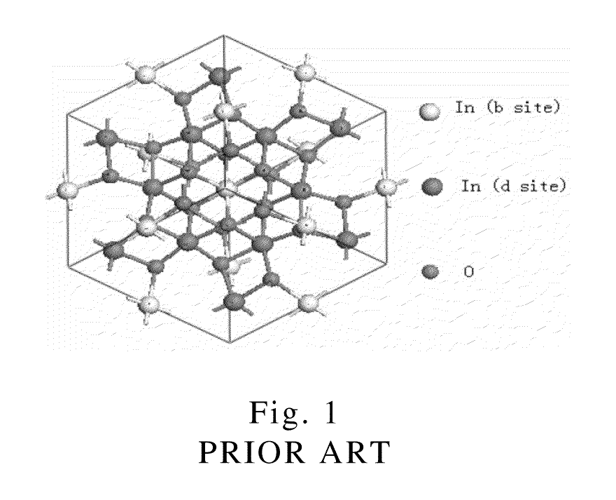

FIG. 2 is a schematic diagram of the two sites for indium oxide (b-sites and d-sites);

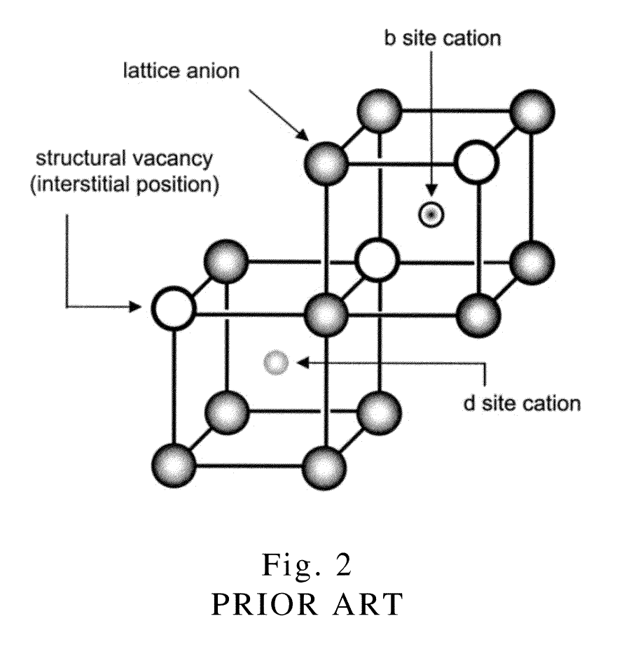

FIG. 3 is a diagram of the I_{D}-V_{D} characteristic curve;

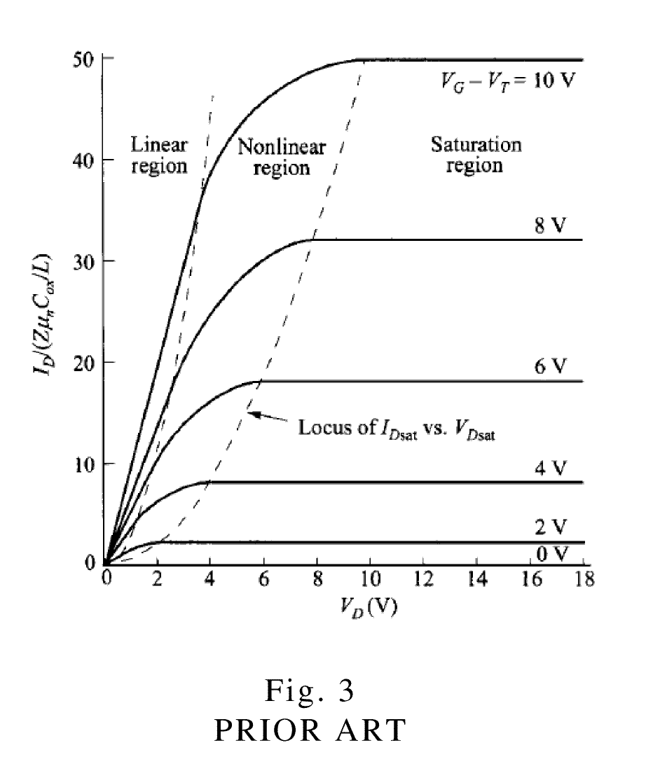

FIG. 4 is a flow chart of the method for making the yttrium-doped indium oxide transparent conductive thin-film transistor and the related analyses;

FIG. 5 is a flow chart of washing the substrate;

FIG. 6 is a flow chart of preparing the solution;

FIG. 7 is a flow chart of fabricating an yttrium-doped indium oxide (YIO) thin film;

FIG. 8 is a flow chart of fabricating an aluminum electrode on the YIO thin film;

FIG. 9 is a flow chart of defining an active layer on the YIO thin film;

FIG. 10 is a schematic diagram of the structure of the yttrium-doped indium oxide transparent conductive thin-film transistor;

FIG. 11 is a schematic diagram of the structure of the yttrium-doped indium oxide transparent conductive thin-film transistor;

FIG. 12 is a schematic diagram of the Hall measurement to obtain R_{A}=V₄₃/I₁₂;

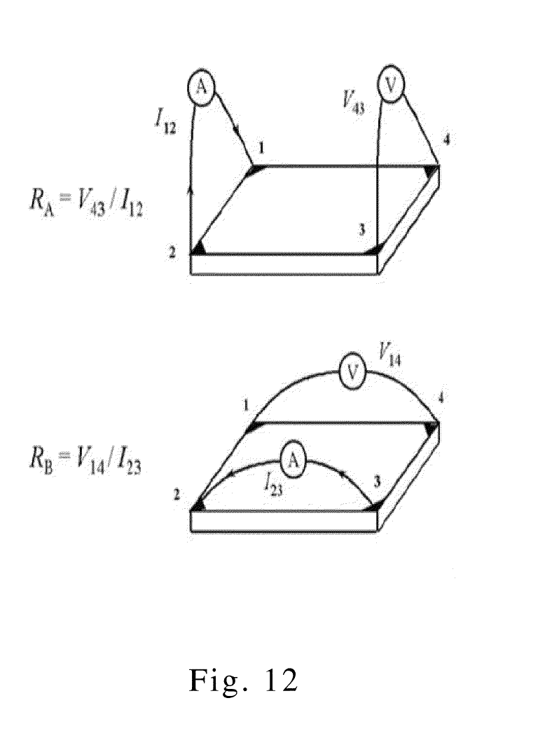

FIG. 13 is a schematic diagram of the Hall measurement to obtain R_{B}=V₁₄/I₂₃;

FIG. 14 is a diagram of I_{D}-V_{D} of the yttrium-doped indium oxide transistor with a doping concentration of yttrium of 0%;

FIG. 15 is a diagram of I_{D}-V_{D} of the yttrium-doped indium oxide transistor with a doping concentration of yttrium of 6%;

FIG. 16 is a diagram of I_{D}-V_{D} of the yttrium-doped indium oxide transistor with a doping concentration of yttrium of 12%;

FIG. 17 is a diagram of I_{D}-V_{D} of the yttrium-doped indium oxide transistor with a doping concentration of yttrium of 20%;

FIG. 18 is a diagram of I_{Ds}-V_{G} and I_{Ds}^{1/2}-V_{G} of the yttrium-doped indium oxide transistor with a doping concentration of yttrium of 12% and the V_{D} is 20V;

FIG. 19 is a diagram of I_{Ds}-V_{G} and I_{Ds}^{1/2}-V_{G} of the yttrium-doped indium oxide transistor with a doping concentration of yttrium of 20% and the V_{D} is 20V;

FIG. 20 is a diagram of I_{D}-V_{G} of the yttrium-doped indium oxide transistors with different doping concentrations and the V_{D} is 5.1V;

FIG. 21 is a diagram of I_{D}-V_{G} of the yttrium-doped indium oxide transistors with different doping concentrations and the V_{D} is 10V;

FIG. 22 is a comparative diagram of the mobility of the yttrium-doped indium oxide transistors with different doping concentrations;

FIG. 23 is a comparative diagram of the S.S of the yttrium-doped indium oxide transistors with different doping concentrations;

FIG. 24 is a comparative diagram of the maximum defect density of the yttrium-doped indium oxide transistors with different doping concentrations;

FIG. 25 is a diagram of the carrier concentration versus the doping concentrations of yttrium and electrical resistivity measured by Hall measurement versus the doping concentrations of yttrium, wherein the doping concentrations of yttrium are 0%, 6%, 12% and 20%;

FIG. 26 is a diagram of the Hall mobility versus the doping concentrations of yttrium, and the doping concentrations of yttrium are 0%, 6%, 12% and 20%;

FIG. 27 is an SEM image of the top section of the YIO transistor;

FIG. 28 is an SEM image of the cross section of the YIO transistor;

FIG. 29 is an AFM image of the transistor with a doping concentration of yttrium of 0%, wherein the root-mean-square (RMS) is 0.276 nm and the measuring range is 1 um×1 um;

FIG. 30 is an AFM image of the transistor with a doping concentration of yttrium of 6%, wherein the root-mean-square (RMS) is 0.238 nm and the measuring range is 1 um×1 um;

FIG. 31 is an AFM image of the transistor with a doping concentration of yttrium of 12%, wherein the root-mean-square (RMS) is 0.212 nm and the measuring range is 1 um×1 um;

FIG. 32 is an AFM image of the transistor with a doping concentration of yttrium of 20%, wherein the root-mean-square (RMS) is 0.374 nm and the measuring range is 1 um×1 um.

FIG. 33 is an UV-Vis diagram of the indium oxide thin films doped with different doping concentrations of yttrium;

FIG. 34 is a photo energy diagram of the indium oxide thin films doped with different doping concentrations of yttrium;

FIG. 35 is a comparative diagram of GIXRD of the indium oxide thin films doped with different doping concentrations of yttrium, GIXRD of In2O3 and GIXRD of JCPD;

FIG. 36 is a diagram of oxygen distribution of the indium oxide thin film;

FIG. 37 is a diagram of oxygen distribution of the indium oxide thin film affected by doping with a doping concentration of yttrium of 6%;

FIG. 38 is a diagram of oxygen distribution of the indium oxide thin film affected by doping with a doping concentration of yttrium of 12%;

FIG. 39 is a diagram of oxygen distribution of the indium oxide thin film affected by doping with a doping concentration of yttrium of 20%.

### DETAILED DESCRIPTION OF THE PREFERRED EMBODIMENTS

The present invention provides a transparent conductive thin-film transistor fabricated by using an yttrium-doped indium oxide thin film as an active layer. The concentrations of yttrium doped into the indium oxide system are varied in the present invention. Sol-gel process is used to prepare an indium oxide solution and the prepared solution is spin coated on a P++ Si substrate with an 80 nm-thick SiO₂ layer, and then the substrate is put into a high temperature furnace to perform the sintering process for fabricating a thin film. The surface of the resulting thin film is analyzed by AFM and SEM, the crystalline state of the resulting thin film is analyzed by GIXRD, the elemental composition of the dopant is analyzed by XPS and the transmittance of the thin film is determined by UV-VIS. Moreover, when fabricating a transistor, the leakage current is reduced by defining the position of an active layer of the transistor. The electrical characteristics of the transistor are analyzed to reach the optimized results.

For a better understanding about the technical features of the present invention and its effect, and for implements in accordance with the disclosures of the specification, preferred embodiment, details and figures are further shown as follows:

### First Embodiment

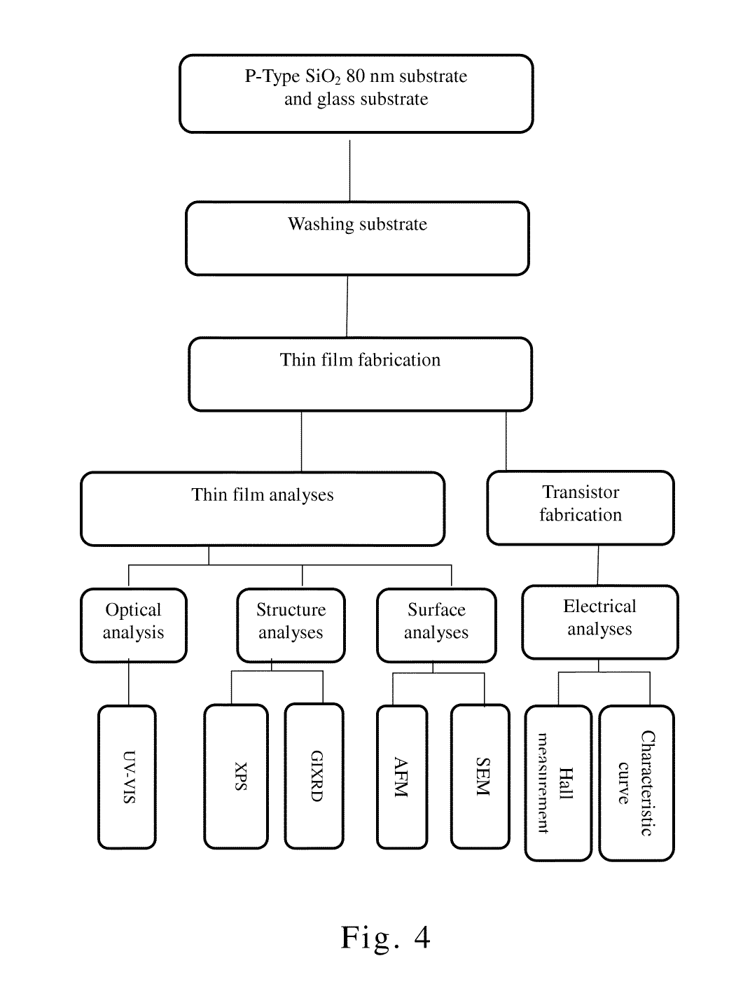

This is an embodiment illustrative of the equipments, instruments, and materials involved in the relative analyses and the fabrication of the transparent conductive thin-film transistor with an yttrium-doped indium oxide thin film as an active layer. The material, processing equipments and analyzing instrument involved in the relative analyses and method as shown in FIG. 4 for making the same of the present invention are shown in Table 6 and Table 7.

TABLE 6

| Reagents and consumables | Specifications | Supplier |
|---|---|---|
| P+ silicon wafer | Lattice orientation | Wafer Works |
| | (100), electrical | Corporation |
| | resistivity | |
| | 0.001~0.025 Ω | |
| Acetic acid (Hac, C₂H₄O₂) | Purity: 99.5% | Alfa Aesar, U.S.A |
| 2-Methoxyethanol | Purity: 99.5% | Merck, Germany |
| (2-MOEC₃H₈O) | | |
| Indium(III) nitrate hydrate, | Purity: 99.99% | Alfa Aesar, U.S.A |
| In(NO₃)₃•xH₂O) | | |
| (Yttrium(III) oxalate | Purity: 99.9% | Alfa Aesar, U.S.A |
| nonahydrate, | | |
| Y₂(C₂O₄)₃•9H₂O) | | |
| Acetone (CH₃COCH₃) | Purity: 99.5% | Mallinckrodt |
| | | chemicals |
| Isopropanol (C₃H₈O) | Purity: 99% | J. T. Baker |
| Positive photo resist | AZ 4620 | AZ |
| Tetramethylammonium | Purity: 99.9999% | Alfa Aesar, U.S.A |
| hydroxide, (CH₃)₄NOH) | | |
| Aluminum ingot | Purity: 99.999%, | LJ-UHV corporation |
| | 6 mm * 6 mm | |
| Positive photo resist | TR-400 | eChem Solutions |
| | | Corporation. |

TABLE 7

| | |
|---|---|
| Electronic balance | The electronic balance was manufactured by |
| | Sartorius Corp. (Germany) and the product type |
| | was CP124S. |
| Heating-magnetic- | The product type of the |
| agitator | heating-magnetic-agitator was fargo HMS-520. |
| Stirrer | The product type of the Stirrer was fargo |
| | MS-100. |
| Spin coater | The spin coater had a function of setting |
| | two-stage rotational speed |
| Tube furnace | The tube furnace was manufactured by |
| | Chitun. Corp. The temperature of the tube |
| | furnace could reach up to 1400° C. |
| Metallographic | The metallographic microscope was |
| microscope | manufactured by Olympus Corp. (Japan) and |
| | the product type was BX-51M. |
| High resolution X-ray | The HDXRD was from Instrument Center at |
| diffractometer (HDXRD) | National Chung Hsing University and was |
| | manufactured by BRUKER |
| | AXSCorp.(Germany). The product type was |
| | D8 Discover SSS. The scanning range was |
| | 10 to 80 degrees. |
| Atomic force microscope | The AFM was from Instrument Center at |
| (AFM) | National Sun Yat-sen University. |
| Field emission scanning | The FE-SEM was from Instrument Center at |
| electron microscope | National Chung Cheng University and the |
| (FE-SEM) | product type was Hitachi S4800-I. The |
| | acceleration voltage was 0.1 to 30 KV. The |
| | magnifying power was 30 to 800,000X. The |
| | emission source was a cold-cathode electron |
| | beam gun. The size of sample was100 mm |
| | diameter. The resolution of the secondary |
| | electron image was 1.0 nm (at 15 kV) or |
| | 2.0 nm (at 1 kV). |
| X-ray photon electron | The XPS/ESCA was from Instrument Center at |
| spectroscopy | National Cheng Kung University |
| (XPS/ESCA) | |
| 4-point probe | The 4-point probe was manufactured by Fluka |
| | Corp. (USA) and the product type was 8845A. |
| Hall measurement | A Self-made instrument. Van der Pauw |
| | technique was used to measure Hall effect. The |
| | magnetic field was 0.5 Tesla. |
| UV-visible | The product type of the UV-visible |
| spectrophotometer | spectrophotometer was HP 8543. The |
| | UV-visible spectrophotometer was able to |
| | analyze the properties of reflection, absorption |
| | and transmittance with a wavelength range of |
| | 190 nm to 1100 nm. |
| UV mask aligner | The UV Mask aligner was from Professor |
| | Wen-Hsin Hsieh's lab of the Department of |
| | Mechanical Engineering at National Chung |
| | Cheng University and the product type was |
| | AG500-4N-D-SM-H. The mercury lamp of the |
| | UV mask aligner provided parallel light and |
| | utilized a shutter with an exposure counter |
| | function. The wavelength of the mask aligner |
| | was 365 nm |
| Evaporator | Professor Chia-Chen Hsu's lab at National |
| | Chung Cheng University provided the |
| | evaporator and the vacuum level could reach |
| | below 10⁻⁶ torr. |

The following analyzing instruments are related to analyses of the transparent conductive thin-film transistor with an yttrium-doped indium oxide thin film as an active layer.

1. Electrical Characteristics Measurement Equipment: Keithley 2400

The present embodiment illustrated the electrical characteristics measurement of the present invention. Two Keithley 2400 was used to measure I-V curve, wherein one of the two Keithley 2400 provided the drain voltage and the other one provided the gate voltage. The probe station was placed in the dark chamber to measure I_{ds}-V_{d} and I_{ds}-V_{g} characteristic curves. The I_{ds}-V_{d} and I_{ds}-V_{g} characteristic curves were used to calculate parameters of transistors.

2. Scanning Electron Microscope (SEM)

The SEM in the embodiment of the present invention was from Instrument Center at National Chung Cheng University. In a typical SEM, an electron beam is emitted from an electron gun and the electron beam is accelerated by a 0.2 to 40 KV voltage. The accelerated electron beam is further focused by an electro-optical system composed of magnetic lens to be a micro electron beam to hit on the sample surface. The scanning coil is used to deflect the electron beam and thus allows the electron beam to proceed with a two-dimensional scanning on the sample surface, and the scanning on the sample surface is in synchronization with the scanning of the cathode ray tube (CRT). The primary electron beam interacts with the sample, resulting in the reflection of high-energy electrons and emission of secondary electrons, each of which can be detected by detectors. The signal is transmitted to the CRT after signal processing and amplifying by the detector, and the brightness and the contrast of the CRT are altered according to the intensity of the detected electronic signals. Because the signal intensity of random position on the sample surface corresponds to the brightness of the corresponding point of the CRT screen, the topography, features, etc. of the sample surface can be presented by the method of synchronization in brightness and imaging.

When the electron beam scan hits on the sample, secondary electrons, reflection electrons, absorbed electrons, Auger electrons, characteristic X-rays and the cathode luminescence will be generated. In SEM, the formation of imaging is mainly by detecting secondary electrons and reflection electrons. If an EDS accessory is added to the SEM, the characteristic X-rays can be detected to analyze the elemental composition of the sample.

3. Grazing Incident X-ray Diffraction (GI-XRD)

The embodiments of the invention used the Grazing Incident X-ray Diffraction in Instrument Center at National Chung Hsing University. In order to adapt to the structure analysis of the material of nano-polycrystalline thin film, the incident light of the grazing incidence X-ray diffraction of polycrystalline forms a small angle with the sample surface, so when the X-ray enters the sample, the X-ray travels through the thin layer near the surface. As a result, to obtain diffraction signals of the thin layer that are more obvious, only the detector is introduced to do the scan and the incident angle of X-ray is fixed at a low degree when measuring material of nano-polycrystalline thin film.

To analyze the powder crystal by diffraction measurement, Bragg formulation of X-ray diffraction is adopted. The incident light, the scattering vector and the diffraction light are in the same plane as Bragg's law is based on symmetric reflection geometry. By this formulation, the incident angle of X-ray is larger (normally 2θ>10°). Normally, the transmittance depth is about single digit or tens of micrometers. However, the thickness of the thin film applied to the semiconductor device is only tens or hundreds of nanometers, so the conventional powder diffraction method limits the measurement of the thin film material. On the other hand, the incident angle of the grazing incidence X-ray diffraction is extremely small. Normally, the incident angle is smaller than 1 degree and the transmittance depth pf the X-ray is rather shallow. When measuring a sample by grazing incident X-ray diffraction, the incident angle is fixed and the detector is fixed at the 2θ position to do 2θ scan to obtain more obvious diffraction signals of the grown thin layer.

The GI-XRD is used to observe the crystallization degree, and the Scherrer's Formula is used to calculate grain size by the full width at half maximum of the thin film having crystalline phase, as shown in equation 3-1.

$$t = \frac{0.9 λ}{B cos {θ}_{B}} \qquad ( Eq . 3 - 1 )$$

Wherein B is the full width at half maximum and t is the grain size.

4. Atomic Force Microscope (AFM)

The embodiments of the invention used the Atomic force microscope in Instrument Center at National Sun Yat-sen University. The atomic force microscope has an ability of atomic size resolution. The atomic force microscope is mainly composed of a probe tip, a position-sensitive photodetector, a feedback system, a scanner and a computer. When the probe tip is extremely near the sample surface, a force between the probe tip and the sample surface is generated, which is the van der Waals force. The van der Waals force changes according to the distance between the probe and the sample, and further the van der Waals force will affect the extent of bending of the cantilever. A laser hits the end of the cantilever, and a photodetector composed of photodiodes is used to measure the change of the reflective angle of the laser. When the probe tip scans through the sample, the different extents of bending of the cantilever cause the different reflective angles of the laser, and the diode current of the photodiodes will change based on the different reflective angles of the laser. The topography of the sample surface is obtained after the change of the current is measured and input to the computer for calculation.

5. X-Ray Photonelectron Spectroscopy (XPS)

The embodiments of the present invention used the X-ray photonelectron spectroscopy in Instrument Center at National Cheng Kung University. Electron spectroscopy for chemical analysis (ESCA) is also known as X-ray photonelectron spectroscopy.

XPS is one of the important techniques of surface analyses, which is able to measure the chemical components on the surface and determine the elemental composition. XPS is usually used to identify whether a chemical action on the surface of the material exists or not and is widely used in the chemistry and material fields.

When X-ray illuminates atoms, the electrons can be ionized to be free electrons if the energy of the X-ray is larger than the binding energy of an inner shell electron (Ez), and the free electrons are named photoelectrons. Because X-ray is used to excite photoelectrons, the photoelectric effect is named X-ray photonelectron spectroscopy. The principle of conservation of energy, the kinetic energy of photoelectrons can be shown as

Eₖ=hν−E_{z} (Eq. 3-2)

Wherein Eₖ is the kinetic energy of a photoelectron, h is the Planck constant, and ν is the frequency of the X-ray.

Moreover, photoelectrons are emitted from the solid-state surface, so the work function of the electrons escaping from the solid-state surface is also taken into consideration. The work function w is shown as

Ek=hνEz−w (Eq. 3-3)

A phenomenon of interchanging between electrons occurs due to the valence electrons of the atoms of a compound participating in bonding, so the atoms are not neutral. The elements with high electronegativity have a negative charge while the elements with low electronegativity have a positive charge, so the inner shell electrons are affected by the static electric field and change the energy levels. The positive charge will cause the reduction of kinetic energy of the photoelectrons of elements, that is, the binding energy of the photoelectron measured by analyst is higher than the binding energy of the atomic state. On the contrary, the measurement of the binding energy of the photoelectron of elements with a negative charge will shift to a lower value.

6. UV-Vis Spectrophotometer

The embodiments of the present invention used UV-Vis spectrophotometer to measure the transmittance of the yttrium-doped indium oxide thin film and then the transmittance is used to calculate the optical band gap.

When a light illuminates electrons of a molecule, the electrons will absorb a specific energy. In general, different energies of light in a range of UV-Vis cause different electron excitations, generating the UV-Vis spectra. Because each specific functional group has a specific absorbing wavelength, the UV-Vis spectra are used to take quantitative measurement of the functional groups of a molecule.

The absorption theory is:

A=log I₀/I=−log T (Eq. 3-4)

Wherein I₀ is the intensity of the incident light and I is the intensity of the transmitting Light.

The calculation of the optical band gap is:

$$\begin{matrix}α hv = {D ( hv - {E}_{g} )}^{m} & ( Eq . 3 - 5 ) \\ T = {( 1 - R )}^{2} {e}^{- α d} & ( Eq . 3 - 6 ) \\ If R ≪ 1 \\ T - {e}^{- α d} & ( Eq . 3 - 7 ) \\ ln T = - α d & ( Eq . 3 - 8 ) \\ α = - \frac{ln T}{d} & ( Eq . 3 - 9 )\end{matrix}$$

The equation 3-9 is substituted into equation 3-5 as

$${( α hv )}^{\frac{1}{m}} = hv - Eg \qquad ( Eq . 3 - 10 )$$

A plot of (αhν)² _{versus hν is made and the X intercept is the Eg.}

7. Van der Pauw Measurement and Hall Effect

As mentioned in Van der Pauw, L. J. Philips Res. Repts, 13, 1-9 (1958), the Van der Pauw method is used to measure the electrical resistivity. Eight data including R_{12,34}, R_{34,21}, R_{43,12}, R_{34,21}, R_{14,23} and R_{41,32} are obtained by a 4-point probe. The parallel resistance is R_{A}=(R_{14,23}+R_{41,32}+R_{23,41}+R_{32,14})/4, and the vertical resistance is R_{B}=(R_{43,12}+R_{34,21}+R_{14,23}+R_{41,32})/4. Moreover, the R_{A} and R_{B} should satisfy equation 3-11.

exp(−RA/Rs)+exp(−RB/Rs)=1 (Eq. 3-11)

The equation of electrical resistivity is:

$$ρ = {R}_{s} t = \frac{π}{ln ( 2 )} t \frac{( {R}_{A} + {R}_{B} )}{2} f \qquad ( Eq . 3 - 12 )$$

Where t is the thickness of material; f is a correction factor to correct the equation while the material is in an arbitrary shape.

The equation of f is:

$$f \approx 1 - {( \frac{{R}_{A} - {R}_{B}}{{R}_{A} + {R}_{B}} )}^{2} \frac{ln ( 2 )}{2} - {( \frac{{R}_{A} - {R}_{B}}{{R}_{A} + {R}_{B}} )}^{4} \{ \frac{{( ln 2 )}^{2}}{4} - \frac{{( ln 2 )}^{3}}{12} \} \qquad ( Eq . 3 - 13 )$$

Van der Pauw method and two additional neodymium magnets are used to measure Hall Effect, wherein a small-range and uniform magnetic field between the two neodymium magnets is 0.5 Tesla. The theory is based on the charges experiencing a Lorentz Force and the equation is:

\vec{F}=q\vec{V}×\vec{B} (Eq. 3-14)

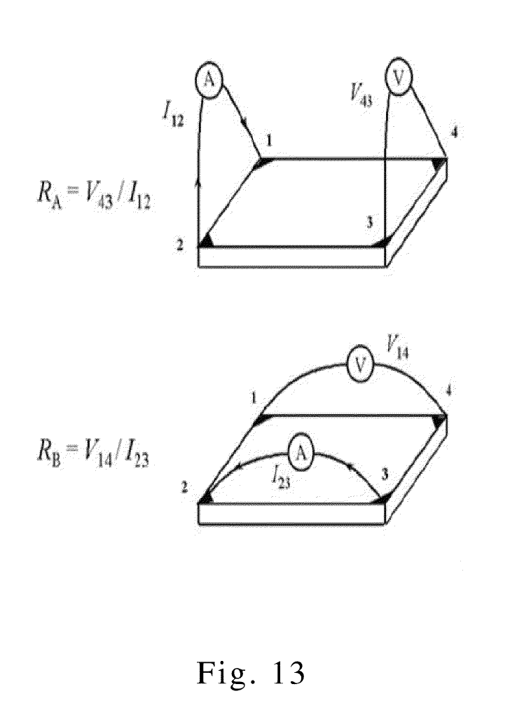

The measurement method is shown in FIG. 13. Eight data including V_{24P}, V_{42P}, V_{13P}, V_{31P}, V_{24N}, V_{42N}, V_{13N}, V_{31N} are obtained by a 4-point probe. The Hall voltage (V_{Hall}) is calculated by

V_{Hall}=(V_{24P}+V_{42P}+V_{13P}+V_{31P})−(V_{24N}+V_{42N}+V_{13N}+V_{31N}) (Eq. 3-15)

V_{Hall} is substituted into equation 3-15 to get sheet concentration (nₛ) and the unit is cm⁻².

$${n}_{s} = \frac{8 \times {10}^{- 8} IB}{q \vert \sum {V}_{Hall} \vert} \qquad ( Eq . 3 - 16 )$$

Where I is an output constant current, B is a magnetic field strength of 0.55 Tesla, q is 1.602×10−19 C unit of charge. The carrier concentration (ne) is calculated by

ne=ns/d (Eq. 3-17)

To calculate Hall mobility, equations 3-13 and 3-17 are substituted into equation

$${μ}_{Hall} = \frac{1}{q {n}_{s} {R}_{s}} \qquad ( Eq . 3 - 18 )$$

### Second Embodiment

The present embodiment relates to the feasible method for fabricating a transparent conductive thin-film transistor by using an yttrium-doped indium oxide thin film as an active layer.

With reference to FIG. 4, the method of the present invention for fabricating a transparent conductive thin-Film transistor by using an yttrium-doped indium oxide thin film as an active layer mainly included the steps of cleaning substrates, preparing thin films, fabricating transistors and so on. The analyses of the prepared thin films and the transistors fabricated by using the prepared thin films could further be done. The analyses of the thin films could be achieved by using optical analysis such as UV-Vis, structure analysis such as XPS and GIXRD and surface analysis such as AFM and SEM. The analyses of the transistors mainly included electrical analysis such as Hall measurement and characteristic curve.

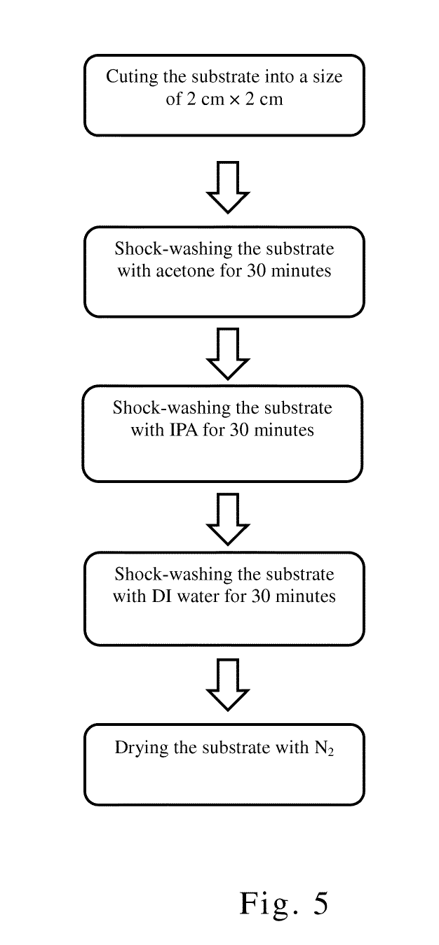

To carry out the illustrative method of the present invention, first of all, a P-type silica substrate of an 80 nm thickness, and a glass substrate (silicon substrate) formed on one surface of the P-type silica substrate were prepared. With reference to FIG. 5, in the present embodiment, the procedure of cleaning the substrate comprised sequential steps as follows:
1. The substrate was cut into a size of 2 cm×2 cm.
2. The 2 cm×2 cm substrate was washed with acetone for 30 minutes.
3. The 2 cm×2 cm substrate was washed with IPA for 30 minutes.
4. The 2 cm×2 cm substrate was washed with DI water for 30 minutes.
5. The 2 cm×2 cm substrate was dried with nitrogen.

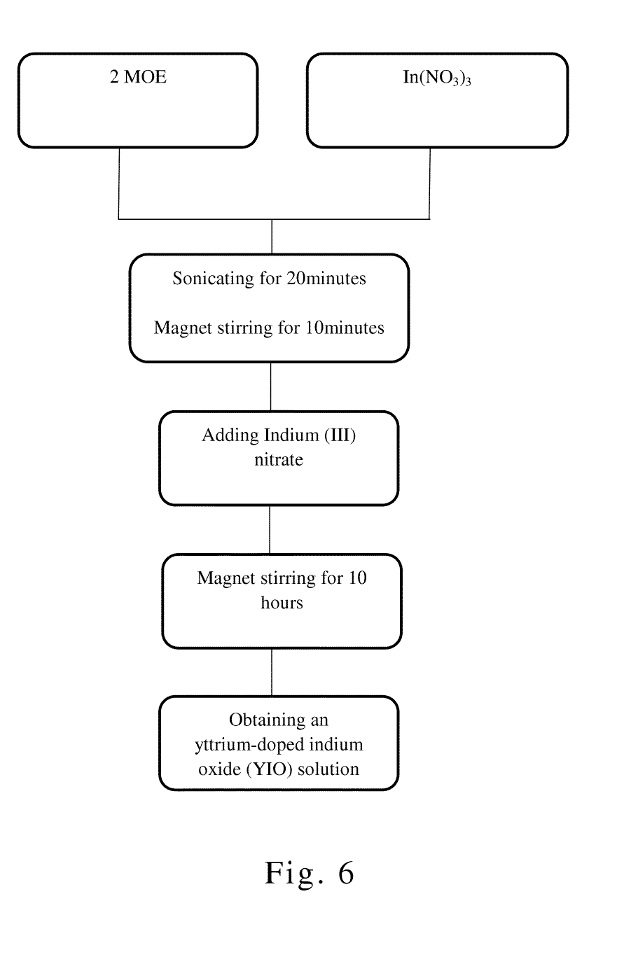

With reference to FIG. 6, before preparing the solution, a detergent and DI water were used to clean needed glasswares, spatulas and stir bars to protect the solution from contamination during preparation. In the present embodiment for preparing the solution, Indium (III) nitrate hydrate was added into the solution of 2-Methoxyethanol of 0.448 M and the solution was put into sonicator to sonicate for 20 minutes. After the Indium (III) nitrate hydrate was broken into pieces by sonication, the solution was stirred for 10 minutes by a heating-magnetic-agitator to make the solution uniformly mixed. Next, yttrium (III) oxalate nonahydrates of different ratios were added into each solution and each solution was stirred for 10 hours by a heating-magnetic-agitator to make the solution uniformly mixed. Finally, the solutions of yttrium-doped indium oxide (YIO) with different ratios of yttrium are obtained.

Sol-gel process was used to fabricate the thin films in the present embodiment. Basically, sol-gel process is an inorganic polymerization. Metal alkoxide (M(OR)n, wherein M is a metal element and OR is an alkoxy group) or inorganic metal compound (ML, wherein M is a metal element and L is anion) is used as precursor source, water is used as hydrolytic agent and alcohol is used as solvent to prepare the polymer-inorganic compound. The precursor is first hydrolyzed with water and undergoes polycondensation to form small particles, and the particle-size distribution is between 1 and 100 nm, and under this situation, the solution is sol-gel. Because the particle size of sol-gel is small, an electric double layer effect occurs due to the effects of electric charges of particles and van der Waals force between particles. As a result, particles collide and undergo Brownian motion, which makes the particles disperse in the solution and not easy to sediment. After a portion of the solution evaporates, the concentration of particles is increased relatively, so the inter-particle interaction increases and then particles connect to each other to form a two-dimensional or three-dimensional web structure, which is the gel state.

Sol-gel process mainly includes hydrolysis and condensation, gelation, aging, drying and densification.

The unique sol-gel process has advantages as follows:

1. Metal alkoxide is used as raw material to avoid the anion contamination.

2. The powder purity is high, the particle-size distribution is narrow and the composition of the powder is uniformly composed.

3. Sol-gel process can be operated at low temperature and the nano particles are easily modified or controlled during the process.

4. Processing such as dipping or spin coating can be operated in the gel state.

After the solution of the present embodiment was prepared, the solution was coated on a glass substrate by spin coating. As mentioned in Bornside, D. et al. Journal of Imaging Technology 13, 122 (1987), the earliest spin coating modeling was proposed by Bornside et al., the spin coating includes four stages: deposition, spinning up, spinning off and evaporation. In the deposition stage, the excess of solution is dropped on the center of the substrate and then the solution covers the entire substrate to avoid uneven thin film due to insufficient solution when undergoing spin coating. Moreover, if particles exist in the solution, a filtration step should be operated in advance to prevent particles from being adsorbed on the substrate, which will crack the substrate.

In the spinning up stage, the solution will be driven to flow outwardly due to the centrifugal force. When reaching the desired rotational speed, the remaining solution will meet the requirement for making the thin film uniform in a desirable time. The thinner the thin film, the more drag force of the remaining solution encounters when flowing, and the higher evaporation efficiency of the solution during the stage. As a result, when the spinning up stage comes to an end, a highly uniform thin film is obtained.

In the process of fabricating thin films, the factors determining the thickness of thin films include: viscosity coefficient of the solution, concentration of the solution, surface tension of the solution, rotational speed of the base, the substrate surface features, the rotation time and so on. Normally, with smaller viscosity coefficient of the solution, higher rotational speed and more rotation time, the thickness of thin films will decrease.

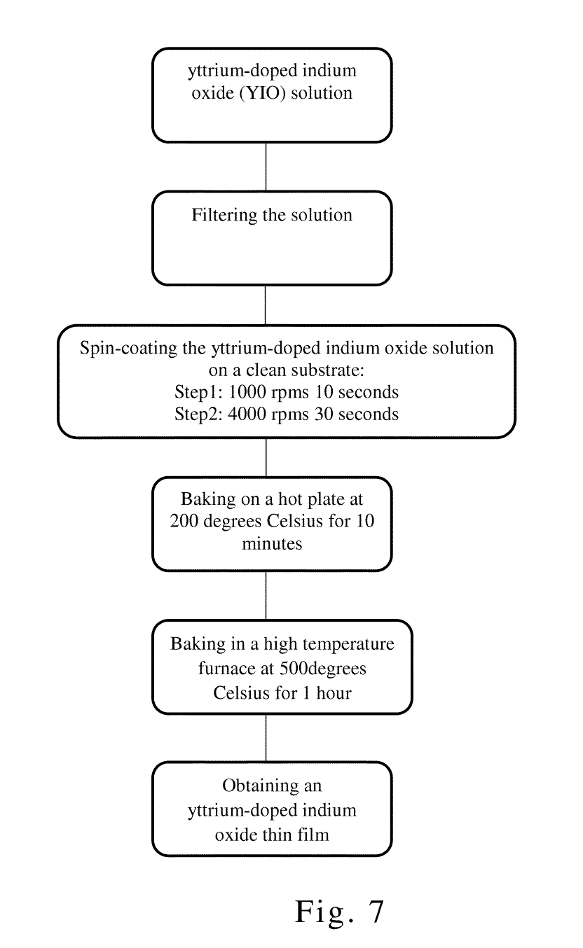

With reference to FIG. 7, the method for making the yttrium-doped indium oxide thin film of the present embodiment comprised sequential steps as follows:

1. A syringe was assembled with a syringe filter to filter the impurity out of the yttrium-doped indium oxide solution to clean the yttrium-doped indium oxide solution.

2. A two-stage spin process was used to spin coat the yttrium-doped indium oxide solution on a clean substrate. During the first stage, the substrate was spun at a speed of 1000 rpm for 10 seconds. During the second stage, the substrate was spun at a speed of 4000 rpm for 30 seconds. A spin-coated substrate was obtained.

3. The spin-coated substrate was put on a hot plate to be baked for 10 minutes at 200° C.

4. The spin-coated substrate was then put into the high temperature furnace to be baked for 1 hour at 500° C.

5. An yttrium-doped indium oxide thin film was obtained.

In the process for fabricating the transistor of the present embodiment, aluminum electrodes were first formed on the yttrium-doped indium oxide thin film by shadow mask, and then an active layer was defined on the yttrium-doped indium oxide thin film.

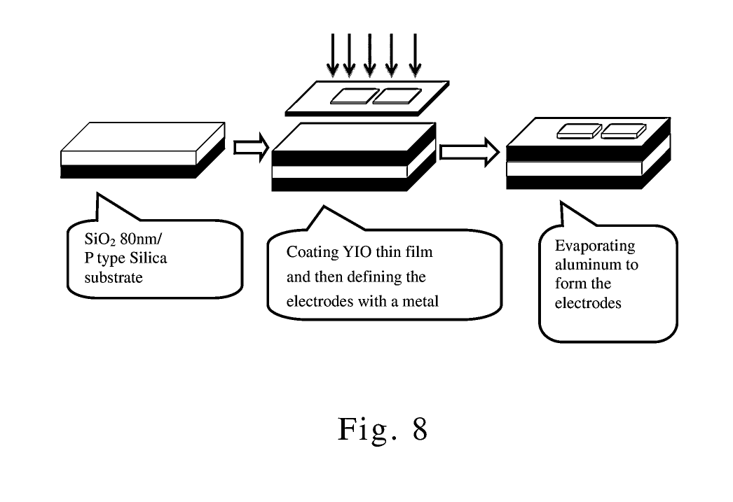

With reference to FIG. 8, after the yttrium-doped indium oxide thin film was formed on the glass substrate on the P-type silica substrate, the electrodes were defined with a metal mask and aluminum was evaporated to form the electrodes on the yttrium-doped indium oxide thin film. An yttrium-doped indium oxide thin film with evaporated electrodes was obtained.

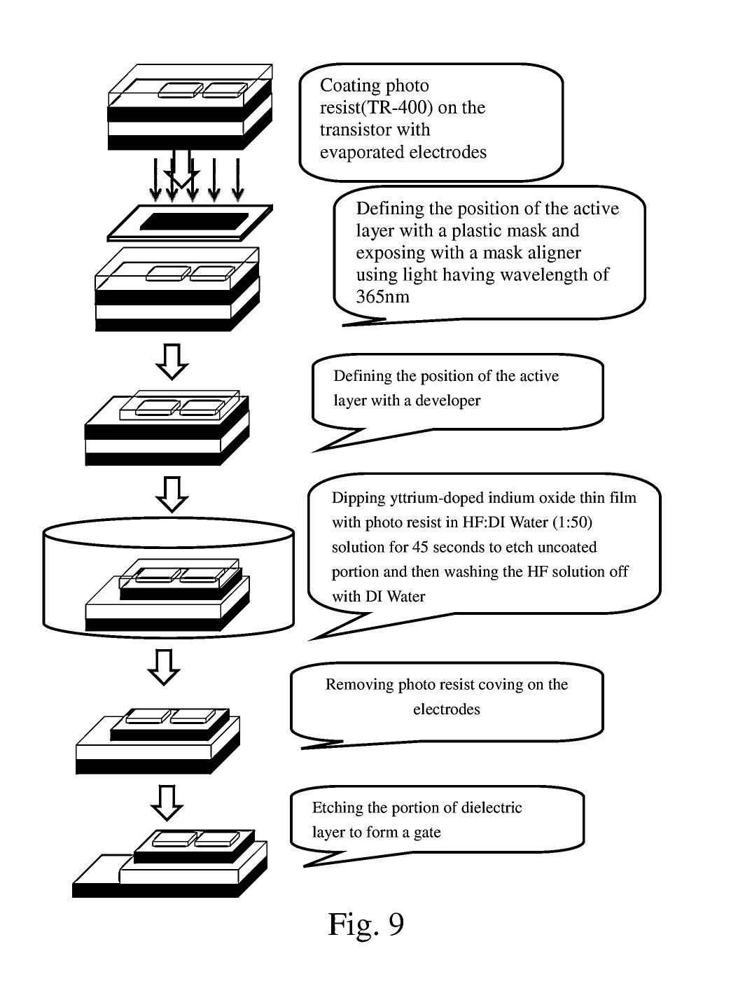

With reference to FIG. 9, in the process for fabricating the transistor of the present embodiment, the sequential steps of defining an active layer were as follows:

1. A photo resist (TR-400) was coated on the yttrium-doped indium oxide thin film with evaporated electrodes.

2. The position of the active layer was defined with a plastic mask. The photo resist was exposed to the intense light wherein the wavelength of the light of the mask aligner was 365 nm.

3. A developer was used to define the position of the active layer. Because TR-400 was a positive photo resist, the portion of the photo resist that was exposed to light was removed through the developer. An yttrium-doped indium oxide thin film with photo resist was obtained.

4. The yttrium-doped indium oxide thin film with photo resist was dipped into a hydrofluoric acid solution diluted with water by 50 times (HF:DI Water (1:50)) for 45 seconds. Hydrofluoric acid solution was used to etch the portion of yttrium-doped indium oxide thin film without photo resist coating, and DI water was used to remove remaining hydrofluoric acid solution. An yttrium-doped indium oxide thin film with an active layer was obtained.

5. Acetone was used to remove the photo resist covering on the electrodes.

6. Hydrofluoric acid solution was used to etch the portion of dielectric layer, namely, the portion of the silicone substrate was etched to reveal the P-type silica substrate to form a gate.

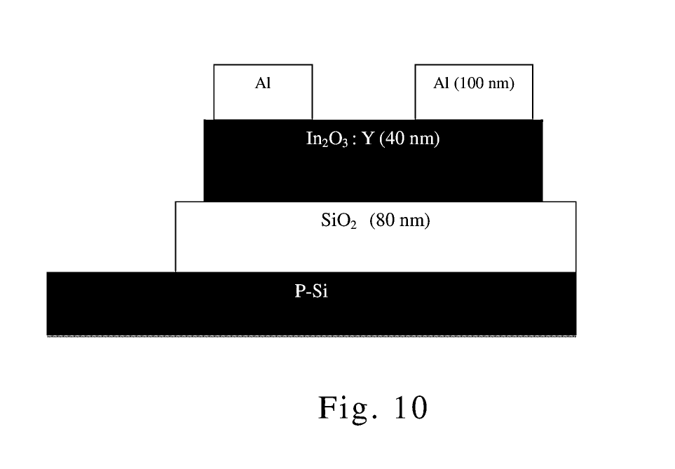

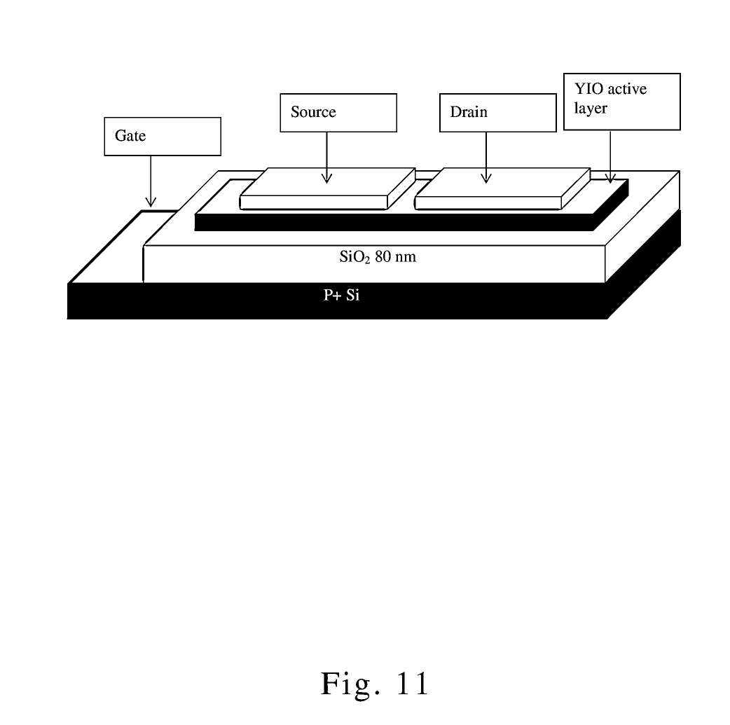

7. A transistor as shown in FIG. 10 and FIG. 11 was obtained.

The transistor of the present embodiment was a top-contact transistor. With reference to FIG. 11, sol-gel process was used to fabricate an yttrium-doped indium oxide thin film as the active layer. The advantages of the present invention were achieved by changing the doping concentrations of yttrium of the transistors. A mask aligner and exposure system were used to define the position of the active layer, and aluminum was evaporated through evaporator to form a 100 nm electrode. The channel length and the channel width were 1000 μm and 100 μm respectively. The thickness of the yttrium-doped indium oxide thin film was about 40 nm.

### Third Embodiment

The present embodiment relates to the electrical characteristics of the yttrium-doped indium oxide transistors.

Yttrium-doped indium oxide thin films with different doping concentrations of yttrium were used in the present invention. Yttrium-doped indium oxide thin films of Y0%, Y6%, Y12% and Y20% were used, that is, the doping concentrations of yttrium were 0%, 6%, 12% and 20% respectively to study the effect of different doping concentrations of yttrium on properties of transistors.

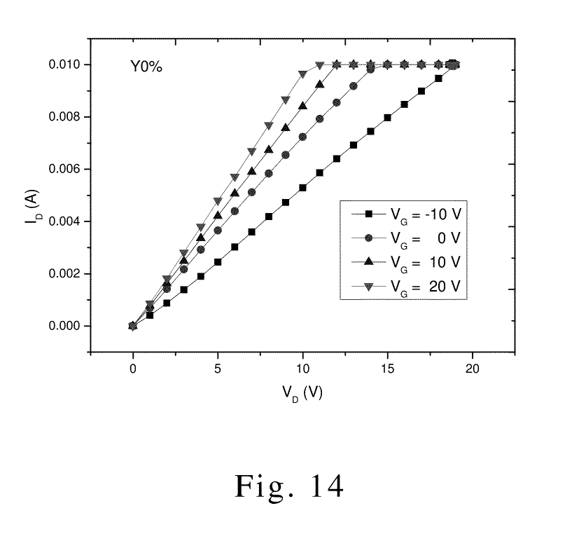

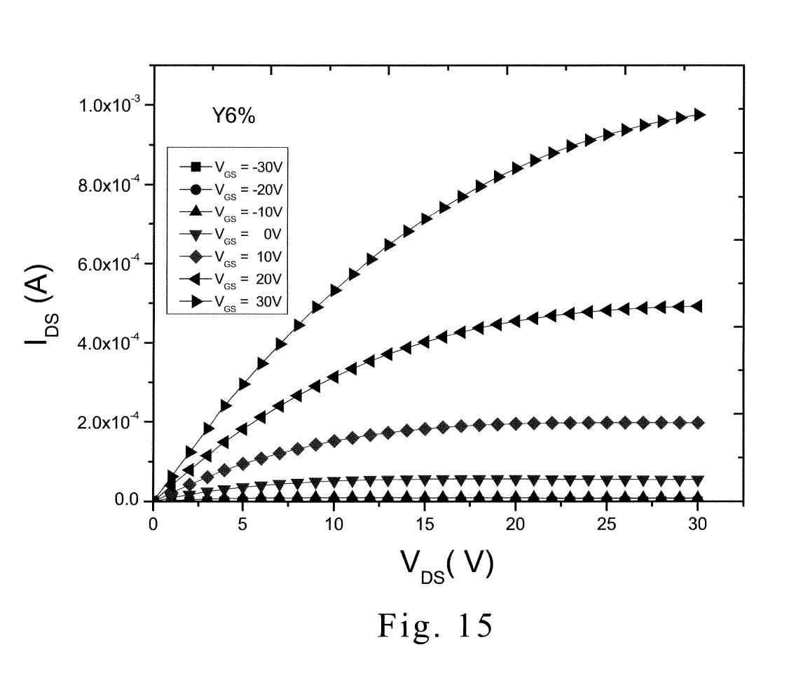

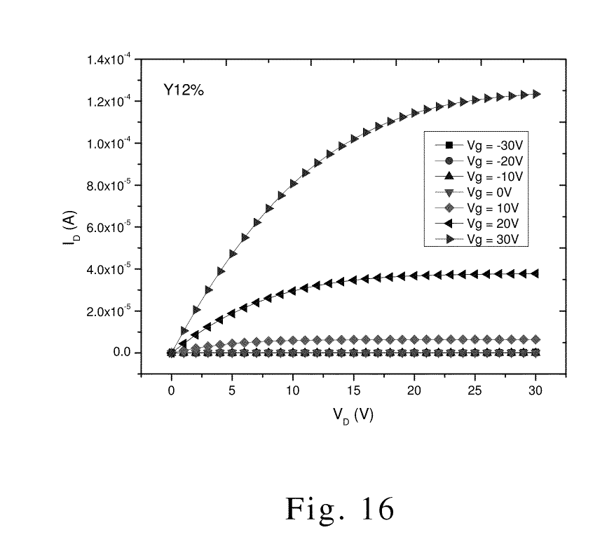

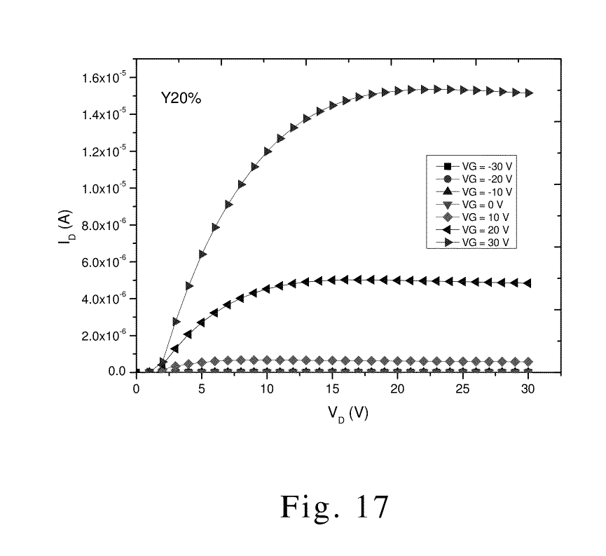

Diagrams of I_{D}-V_{D} of the yttrium-doped indium oxide transistors with different doping concentrations of yttrium are shown in FIG. 14 to FIG. 17. When the doping concentration of yttrium is 0%, the electrical conductivity of the yttrium-doped indium oxide thin film is high. Besides, the diagram of I_{D}-V_{D} shows linear region but no saturation region. When the doping concentration of yttrium is 6%, the transistor has transistor characteristics, but the channel is not fully pinched-off, as the diagram shows no saturation region. When the doping concentrations of yttrium are 12% and 20%, both of the diagrams show saturation regions. The diagrams indicate that carrier concentration and current decrease as the doping concentrations of yttrium increase. The channel is pinched-off and the transistor shows full transistor characteristics when the doping concentration of yttrium is 12%.

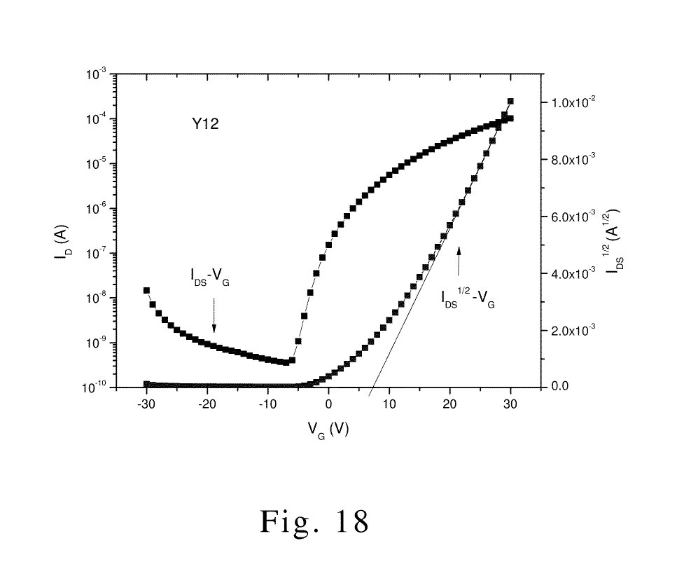

FIG. 18 is a diagram of I_{Ds}-V_{G} and I_{Ds}^{1/2}-V_{G} of the transistor with a doping concentration of yttrium of 12%, the I_{Ds}-V_{G} curve shows that on/off ratio is 2.12×10⁵, and Vₜₕ is determined as 6.69 by the X intercept of the I_{Ds}^{1/2}-V_{G} curve when the V_{D} is 20 V.

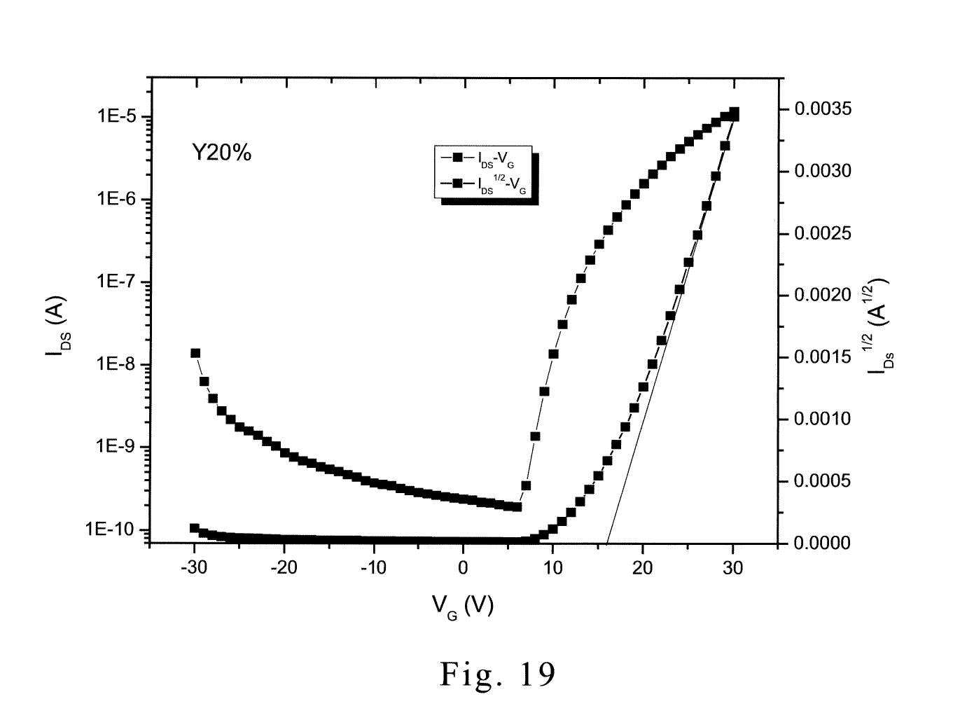

FIG. 19 is a diagram of I_{Ds}-V_{G} and I_{Ds}^{1/2}-V_{G} of the transistor with a doping concentration of yttrium of 20%, and Vₜₕ is determined as 13.25.

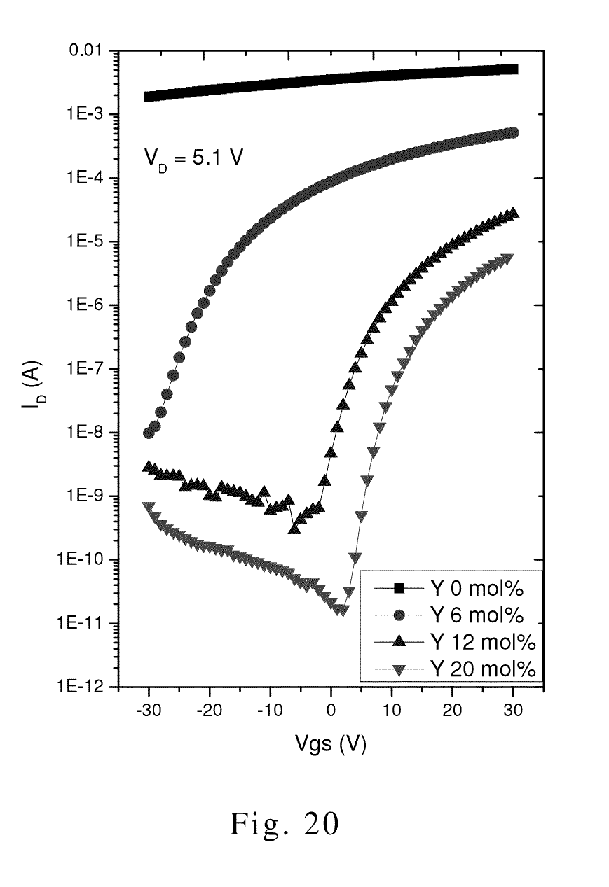

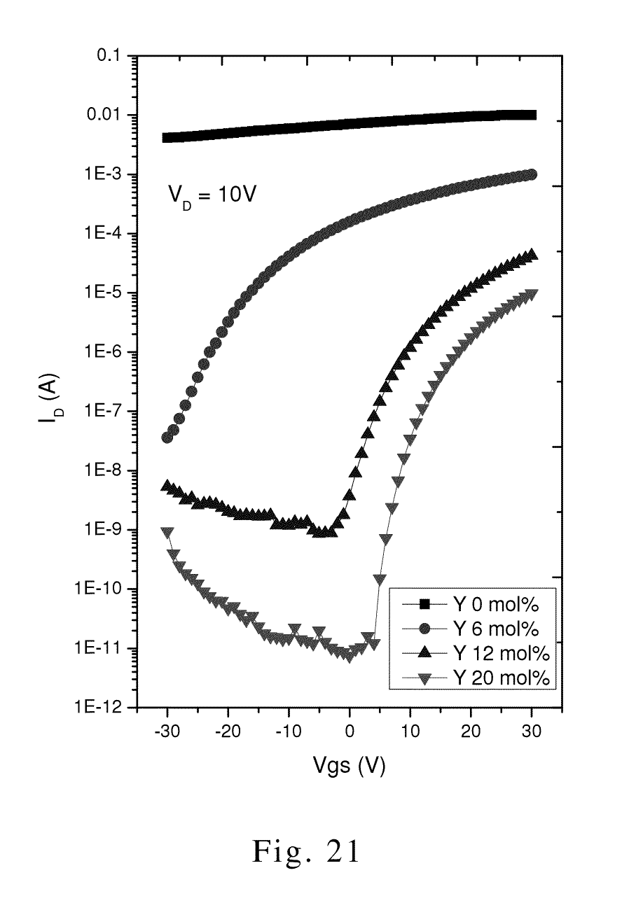

FIG. 20 and FIG. 21 show on/off ratio of transistors with different doping concentrations. The on current decreases with increasing doping concentrations, and the off current also decreases with increasing doping concentrations. The shift of V_{T} is toward positive voltage obviously.

In conclusion, the four yttrium-doped indium oxide transparent conductive thin-film transistors with different doping concentrations of yttrium are tabulated as Table 8 to make comparisons.

TABLE 8

| VD = | On | | I On/Off | S.S | Vth | μFE | |
|---|---|---|---|---|---|---|---|
| 10 V | Current | Off Current | Ratio | (mV/dec) | (V) | (cm²/Vs) | N₁ |
| Y0% | 1.00 × 10⁻² | 4.12 × 10-3 | 2 | 114.55 | −54.79 | 29.9 | 5.18 × 10¹⁴ |
| Y6% | 5.97 × 10⁻⁴ | 4.26 × 10⁻⁸ | 1.4 × 10⁴ | 5.52 | 5.78 | 5.64 | 2.47 × 10¹³ |
| Y12% | 8.29 × 10⁻⁵ | 3.86 × 10⁻¹⁰ | 2.12 × 10⁵ | 2.33 | 6.69 | 1.43 | 1.03 × 10¹³ |
| Y20% | 9.76 × 10⁻⁶ | 7.48 × 10⁻¹² | 1.31 × 10⁶ | 0.91 | 13.25 | 0.26 | 3.84 × 10¹² |

From Table 8, because the carrier concentration is high when the doping concentration of yttrium is 0%, the on-current and the off-current are higher than other transistors, and the mobility is the highest. However, S.S, Vₜₕ and On/OFF ratio do not show transistor characteristics. As a result, the doping concentrations of yttrium were changed to reduce the off-current to optimize the best transistor with best properties. With reference to FIG. 20 and FIG. 21, the on-current and the off-current decrease and the On/Off ratio reaches 1.4×10⁴ when the doping concentration of yttrium is 6%. The On/Off ratio reaches 2.12×10⁵ when the doping concentration of yttrium is 12%. The On/Off ratio reaches 1.31×10⁶ when the doping concentration of yttrium is 20%, which is the highest On/Off ratio of all transistors. A conclusion is obtained that to increase On/Off ratio, the off-current must be decreased. When the doping concentration of yttrium is 20%, the off-current is reduced to a very low value, so the On/Off ratio reaches 10⁶.

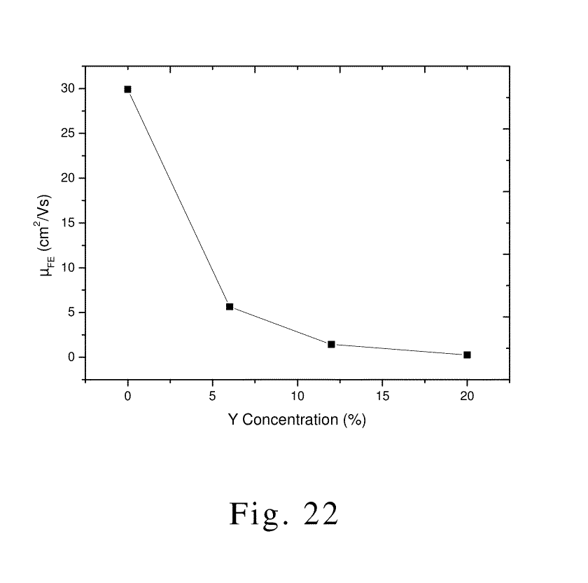

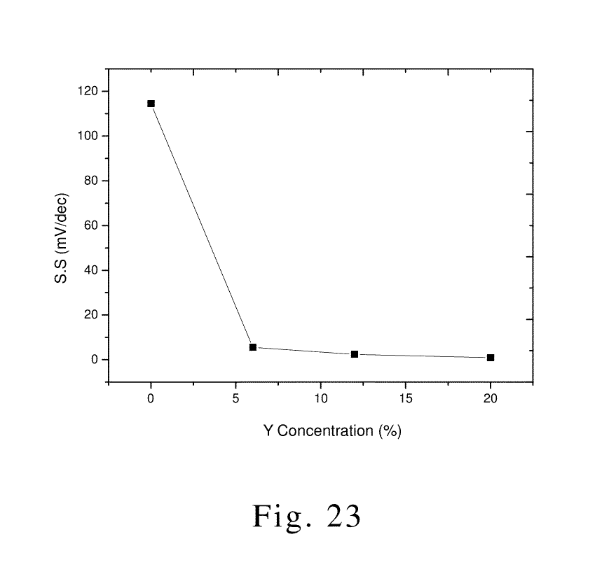

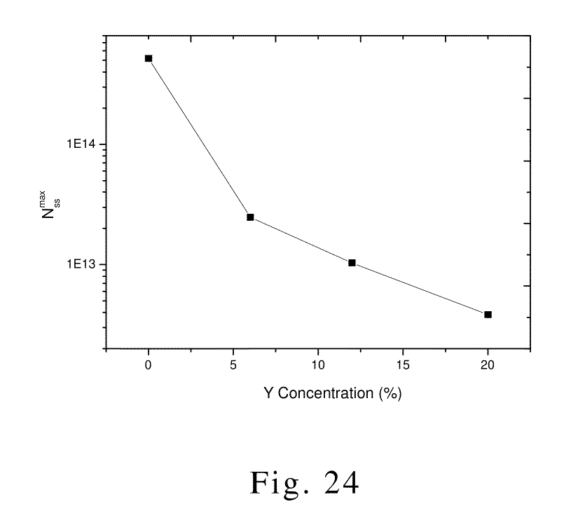

With regard to the aspect of mobility, as shown in FIG. 22, the mobility decreases gradually with increasing doping concentration of yttrium. The mobility of the transistor with the doping concentration of yttrium of 0% is 29.9 cm²/Vs, and the mobility of the transistor with the doping concentration of yttrium of 20% decreases to 0.26 cm²/Vs. Besides, the shift of Vth is toward positive voltage as well when the doping concentration of yttrium is from 0% to 20%. With reference to FIG. 23 and FIG. 24, S.S decreases with the increasing doping concentrations of yttrium, which indicates that maximum defect density will decrease with the increasing doping concentration of yttrium.

The main purpose of doping yttrium into indium oxide system is to suppress carrier concentration. From the electrochemist point of view, the electronegativity difference between yttrium and oxygen is larger than the electronegativity difference between indium and oxygen, so a strong bond is formed between yttrium and oxygen. As a result, doping yttrium can effectively bind oxygen, thus suppressing the formation of oxygen vacancies, reducing carrier concentration, decreasing off-current to increase On/Off ratio, decreasing S.S and decreasing maximum defect density. In conclusion, the transistor with the doping concentration of yttrium of 12% has the optimum transistor characteristics.

### Fourth Embodiment

The present embodiment relates to the electrical characteristics of the yttrium-doped indium oxide thin films.

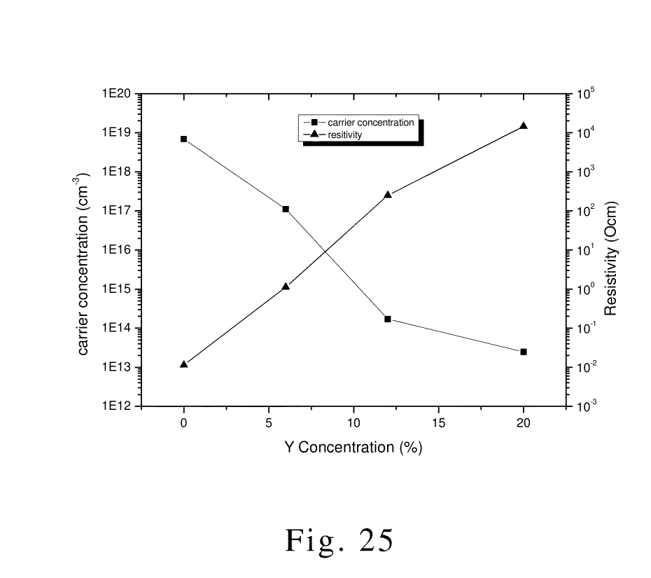

The yttrium-doped indium oxide thin films were measured through Hall measurement. With reference to FIG. 25, when the doping concentration of yttrium is 0%, the carrier concentration is 6.62×10¹⁸. When the doping concentration of yttrium is 6%, the carrier concentration is 1.12×10¹⁷. When the doping concentration of yttrium is 12%, the carrier concentration decreases to 1.7×10¹⁴. When the doping concentration of yttrium is 20%, the carrier concentration is 9.93×10¹³, which is the lowest. The carrier concentration decreases from 10¹⁸ to 10¹³ with increasing concentration of yttrium. With regard to the electrical resistivity, when the doping concentration of yttrium is 0%, the electrical resistivity is only 0.015 Ωcm, which is the lowest. The resistivities are 1.125, 249.5, 1582 Ωcm respectively when the doping concentrations of yttrium are 6%, 12% and 20%.

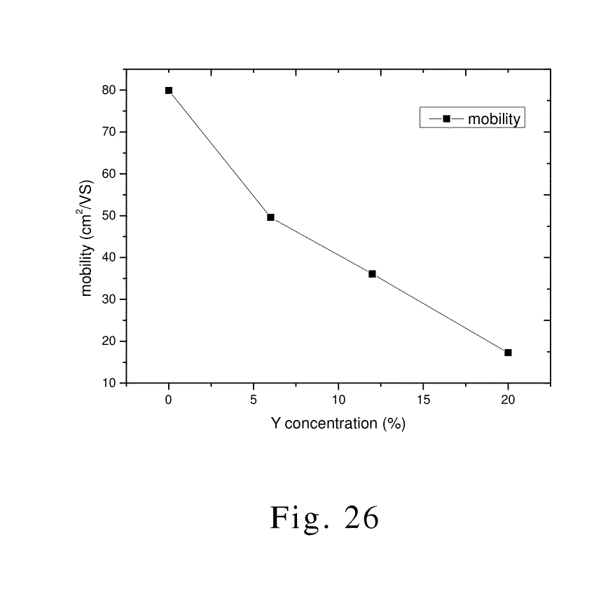

With reference to FIG. 26, from the data obtained by Hall measurement, a conclusion is obtained that with increasing doping concentrations of yttrium, the carrier concentration decreases and the electrical resistivity increases, resulting in decreasing Hall mobility as well.

The electrical resistivity, carrier concentration and Hall mobility of each yttrium-doped indium oxide thin film with a specific doping concentration of yttrium measured through Hall measurement are tabulated in Table 9.

TABLE 9

| | Electrical | Carrier | Hall mobility |
|---|---|---|---|
| YIO | resistivity | concentration | (μHall) |
| Y % | (Ω cm) | (cm⁻³) | (cm²/Vs) |
| Y0 | 0.015 | 6.82E+18 | 79.93 |
| Y6 | 1.125 | 1.12E+17 | 49.61 |
| Y12 | 249.5 | 1.70E+14 | 36.11 |
| Y20 | 14570 | 2.48E+13 | 17.28 |

### Fifth Embodiment

The present embodiment relates to the topographic structures of the yttrium-doped indium oxide thin film determined by SEM.

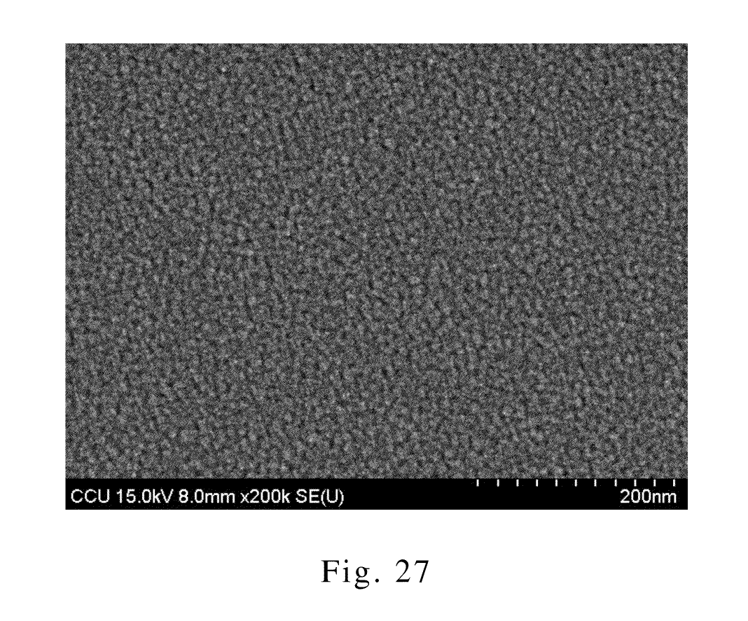

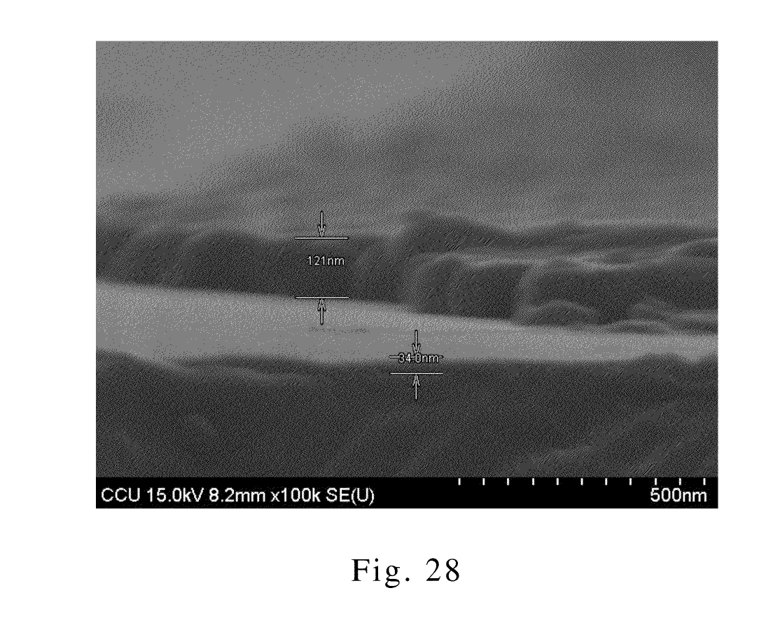

The YIO thin film was observed through SEM respectively, as shown in FIG. 27, after the thin film was sintered at 500° C., the top section of the thin film of the transistor exhibited crystalline grains of about only a few nm. As shown in FIG. 28, the cross section of the thin film of the transistor indicated that the thickness of YIO thin film was about 40 nm, and the aluminum electrode on the YIO thin film was about 100 nm.

### Sixth Embodiment 6

The present embodiment relates to the topographic structures of the yttrium-doped indium oxide thin film determined by AFM.

AFM was used to determine indium oxide thin films doped with different concentrations of yttrium, wherein the indium oxide thin films were grown on the silicon/silica substrate. The topographic structures and the surface roughness of the yttrium-doped indium oxide thin films were observed.

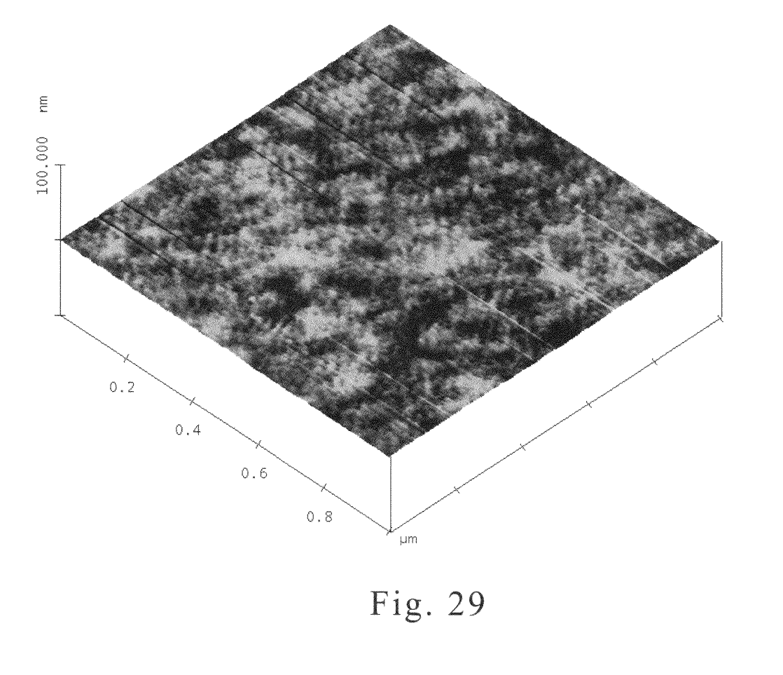

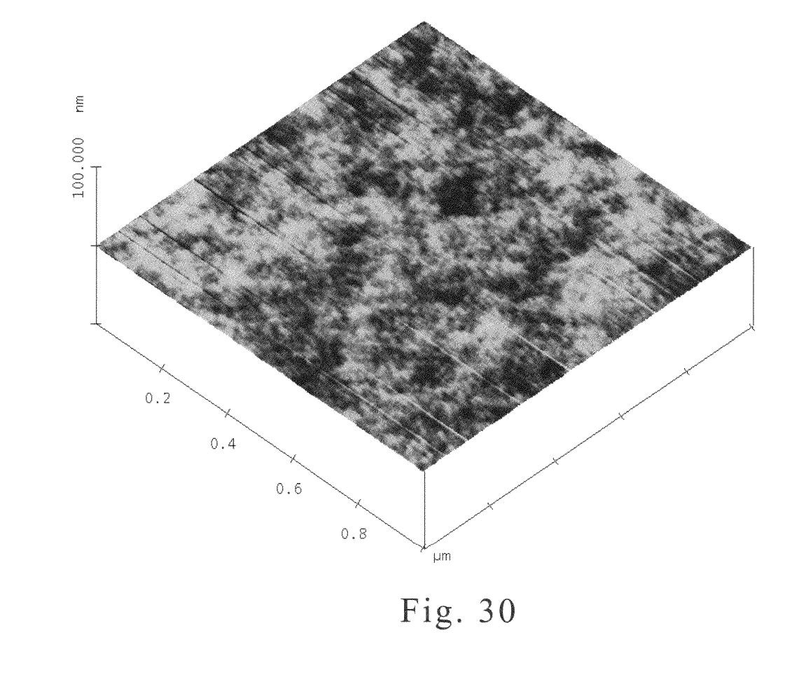

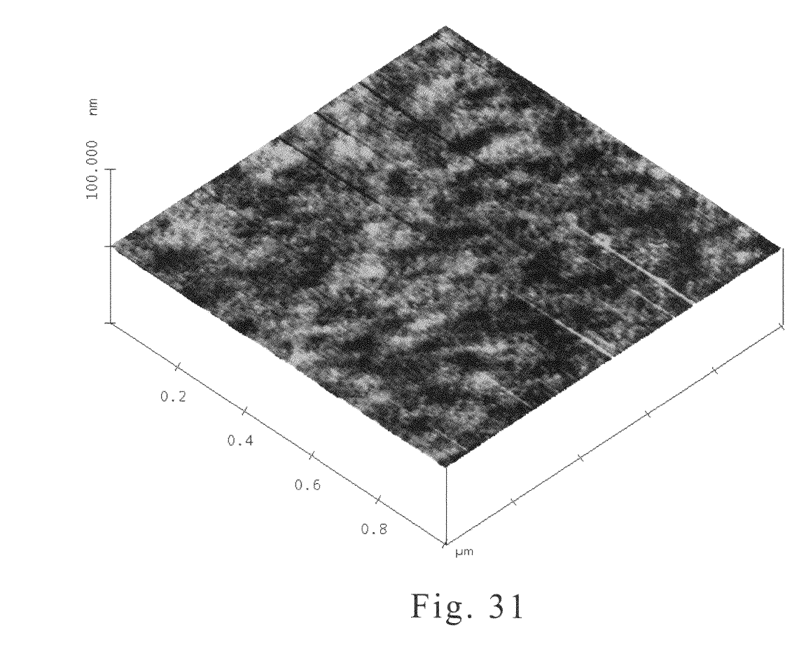

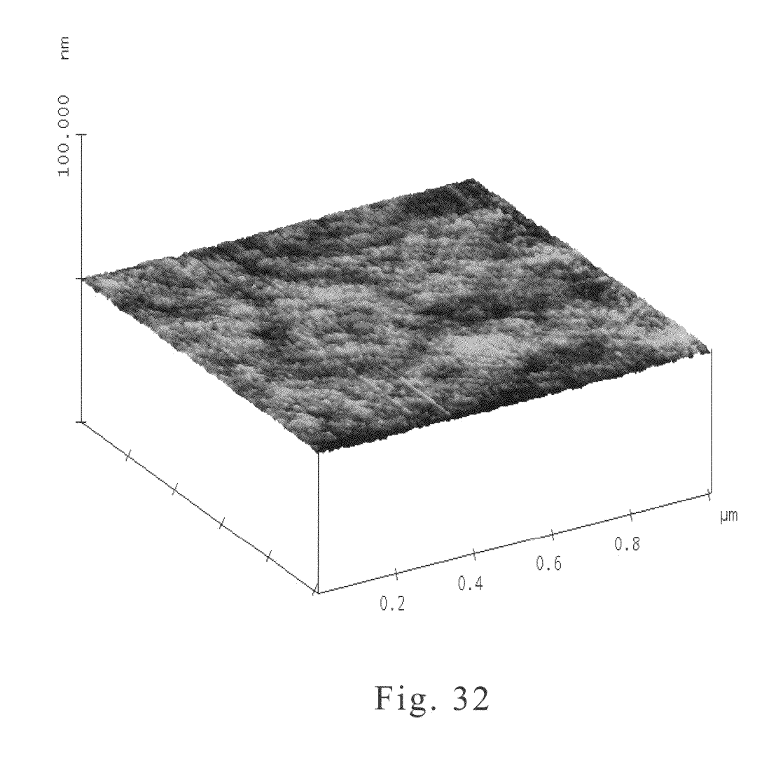

The AFM images of the yttrium-doped indium oxide thin films with doping concentrations of yttrium of 0%, 6%, 12% and 20% are shown in FIG. 29 to FIG. 32, and the measuring range was 1 um×1 um respectively. The results show that when the doping concentration of yttrium is 0%, the surface roughness is 0.276 nm, and when the doping concentration of yttrium increases to 6%, the surface roughness is 0.238 nm. When the doping concentration of yttrium increases to 12%, the surface roughness is 0.121 nm, which is the smallest. However, when the doping concentration of yttrium increases to 20%, the surface roughness increases remarkably to 0.374 nm. The large surface roughness affects mobility of carriers, which results in changing properties of TFTs. The result indicates that the transistor with a doping concentration of yttrium of 12% exhibits the best properties. However, whether the doping concentration of yttrium of the yttrium-doped indium oxide thin film is 0%, 6%, 12% or 20%, the surface roughness is very small, thus improving the properties of the transistor. The effects of the concentration of yttrium on the surface roughness are tabulated in Table 10.

TABLE 10

| | Y0% | Y6% | Y12% | Y20% |
|---|---|---|---|---|
| RMS(root mean | 0.276 | 0.238 | 0.212 | 0.374 |
| square) (nm) | | | | |

### Seventh Embodiment

The present embodiment relates to the optical characteristics such as refractive index and the reflectivity of each yttrium-doped indium oxide thin film. The YIO thin film was first deposited on a glass. The spectroscopic ellipsometer system was used to determine the YIO thin films with different concentrations of yttrium.

Because the thin films comprise indium oxide and yttrium, equation 4-1 is used to calculate the refractive index of each YIO thin film with a specific concentration of yttrium.

n²=η_{Y2O3}n_{Y2O3}²+η_{In2O3}n_{In2O3}² (Eq. 4-1)

Wherein η_{Y2O3} is the concentration of yttrium of YIO, η_{In2O3} is the concentration of indium oxide of YIO. The n_{Y2O3} is known to be 1.79 and the n_{In2O3} is known to be 1.92. As a result, refractive index of each YIO thin film with a specific concentration of yttrium is obtained as shown in Table 11.

TABLE 11

| | | Reflec- | | |
|---|---|---|---|---|
| | Refractive | tivity | | |
| | index | (theo- | (Ellipsometer) | |
| | (theoretical | retical | refractive | (Ellipsometer) |
| Yconcentration | value) | value) | index | reflectivity |
| 0% | 1.84 | 0.087 | 1.6615 | 0.0617 |
| 6% | 1.82 | 0.085 | 1.6513 | 0.0603 |
| 12% | 1.81 | 0.084 | 1.5878 | 0.0516 |
| 20% | 1.80 | 0.082 | 1.5119 | 0.0415 |

As mentioned in Hecht, E. Optic 4th Edition, 1-689 (Addison Wesley, 2002), because the incident light is normal incidence, the reflectivity is calculated by substituting the refractive index of YIO into equation 4-2.

$$R = {( \frac{{n}_{t} - {n}_{i}}{{n}_{t} + {n}_{i}} )}^{2} \qquad ( Eq . 4 - 2 )$$

Wherein nₜ is the refractive index obtained by the method mentioned above, nᵢ is the refractive index of air. As a result, reflectivity of each YIO thin film with a specific concentration of yttrium is obtained. Table 11. shows that when the concentration of yttrium is 0%, 6%, 12% and 20% respectively, the reflectivity is 0.087, 0.085, 0.084 and 0.082 respectively.

Spectroscopic ellipsometer System was used to measure YIO thin films with different concentrations of yttrium, the measuring results were used to calculate reflectivity respectively as shown in Table 11. When the concentration of yttrium is 0%, 6%, 12% and 20% respectively, the reflectivity is 0.0617, 0.603, 0.0516 and 0.0415 respectively. Because the reflectivity obtained by both theoretical value and ellipsometer is small, the reflectivity, is regarded as zero when calculating the energy level in other embodiments.

### Eighth Embodiment

The present embodiment relates to the optical characteristics such as transmittance and optical band gap of each yttrium-doped indium oxide thin film. To study the extent in transmittance of yttrium-doped indium oxide transparent thin-films, the YIO thin film was first deposited on a glass. The UV/VIS Spectrophotometer was used to determine the YIO thin films with different concentrations of yttrium.

The UV/VIS Spectrophotometer was used to determine the YIO thin films with different concentrations of yttrium. The wavelength used was in a range of 320 nm to 760 nm.

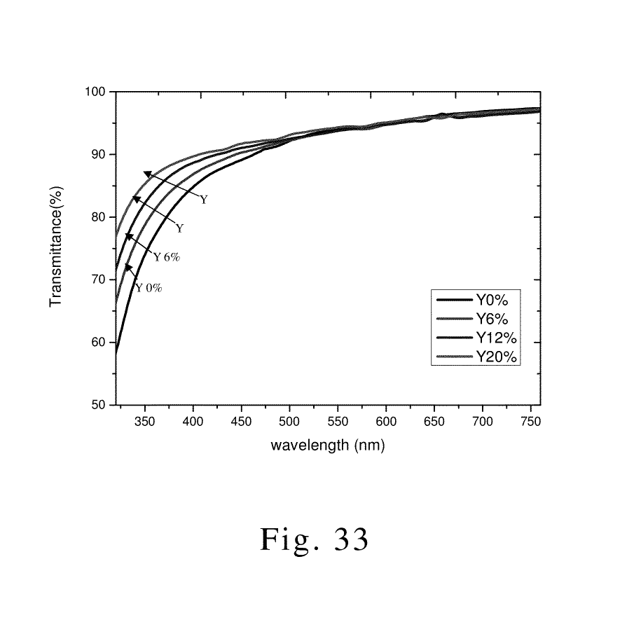

With reference to FIG. 33, whether the concentration of yttrium is 0%, 6%, 12% or 20%, the transmittance is over 85%. The transmittance is even over 90% at visible wavelength, so the YIO exhibits a good transmittance property. At a longer wavelength, the transmittances of YIO thin films with different concentrations of yttrium are not so obviously different from each other, but the main difference is at the shorter wavelength. The trend shifts to the shorter wavelength with increasing concentration of yttrium, and the transmittance range increases as well as the transmittance.

The transmittance is used to calculate optical band gap by substituting into Tau'c equation:

$${( α hv )}^{\frac{1}{m}} = hv - Eg$$

Because YIO is direct band gap, m is ½.

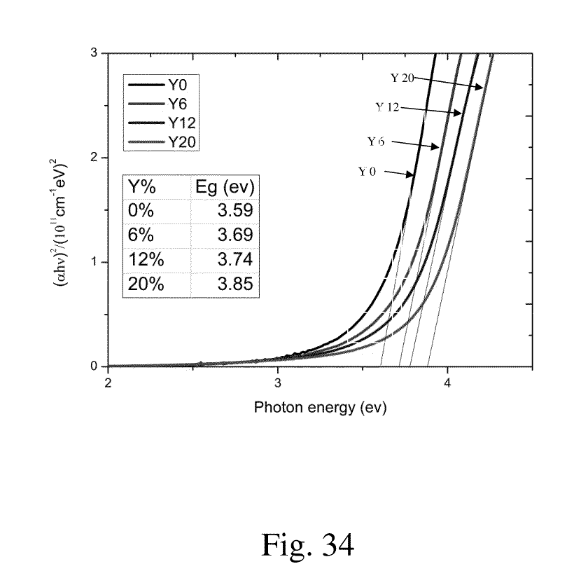

The results are shown in FIG. 34.

The optical band gap increases with increasing concentration of yttrium. When the concentration of yttrium is 0%, 6%, 12% and 20% respectively, the optical band gap is 3.59 eV, 3.69 eV, 3.74 eV and 3.85 eV respectively.

Because the energy gap of indium oxide is 3.6 eV and the energy gap of yttrium oxide is 6 eV, a conclusion is obtained that the optical band gap increases with increasing concentration of yttrium, and the transmitted light increases and shifts to the shorter wavelength. The YIO thin film with a concentration of yttrium of 20% has a largest optical band gap and a largest transmittance.

### Ninth Embodiment

The present embodiment relates to the structure analysis of each yttrium-doped indium oxide thin film determined by GIXRD.

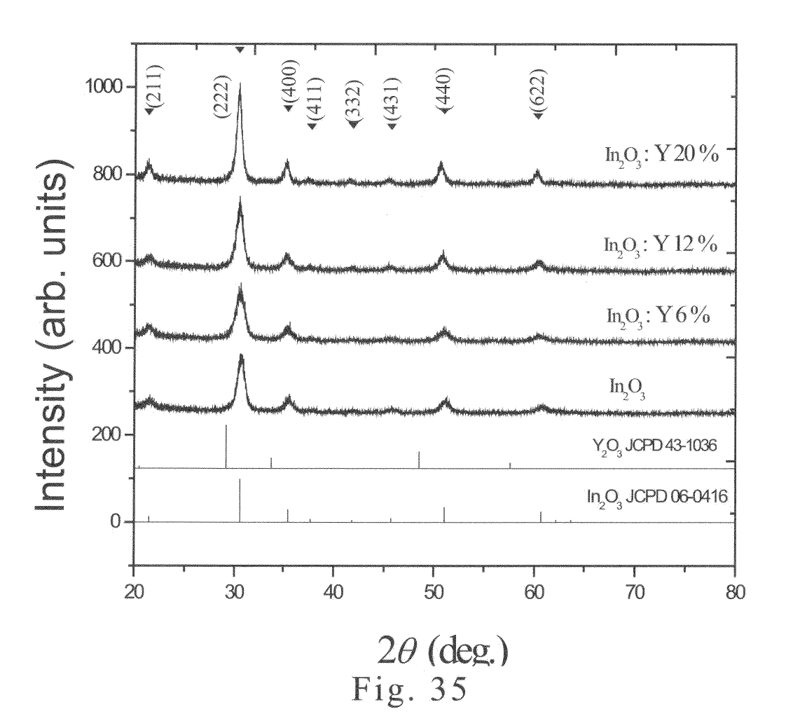

GIXRD was used to determine the structure analysis of each YIO thin film. FIG. 35 shows that the YIO thin film exhibits an obvious crystalline state after being sintered at 500° C. with increasing doping concentration of yttrium. The crystalline state is more obvious since the peak of indium oxide is sharper and the full width at half maximum (FWHM) is smaller.

Comparing YIO with the JCPD card as shown in FIG. 35, the crystalline state is attributed to In₂O₃ phase rather than yttrium phase due to the low concentration of yttrium.

Full width at half maximum can be substituted into Scherrer's Formula, as shown in equation 3-1.

$$t = \frac{0.9 λ}{B cos {θ}_{B}}$$

The grain size of crystalline state of YIO can be calculated and the data are tabulated in Table 12. The grain size is 10.387 when the concentration of yttrium is 0%. The grain size increases with increasing concentration of yttrium, which indicates that crystalline state is formed more easily with increasing concentration of yttrium of the YIO thin film.

TABLE 12

| Concentration | FWHM | Grain Size (nm) |
|---|---|---|
| Y0 | 0.84 | 10.387 |
| Y6 | 0.83 | 10.514 |
| Y12 | 0.63 | 13.999 |
| Y20 | 0.50 | 17.913 |

### Tenth Embodiment

The present embodiment relates to the structure analysis of each yttrium-doped indium oxide thin film determined by XPS.

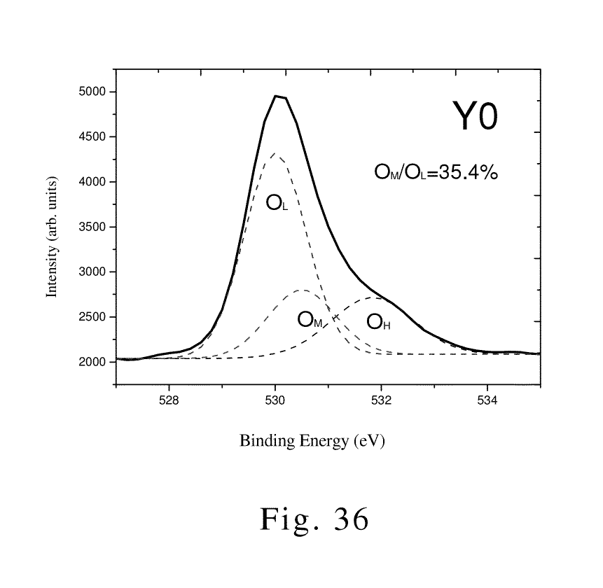

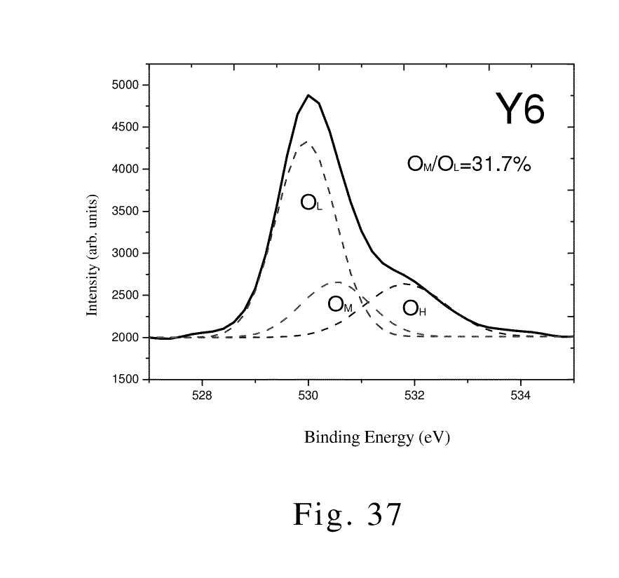

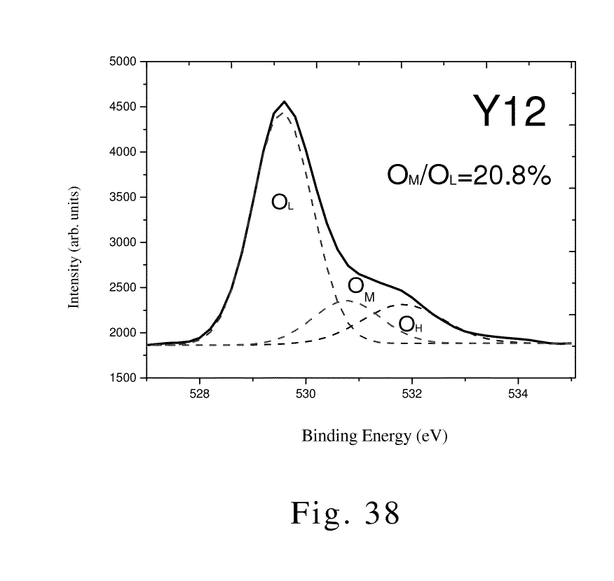

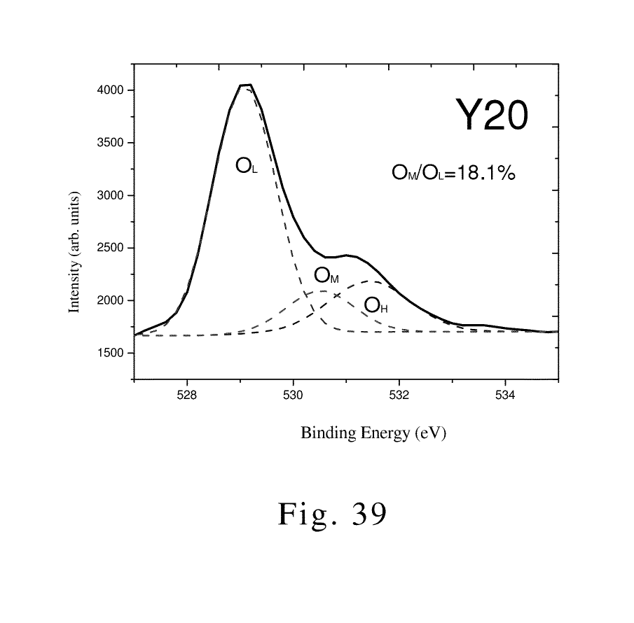

XPS is mainly used to determine the elemental composition of sample surface. O_{M} indicates the amount of oxygen vacancies, O_{L} indicates the amount of bonding between the element to oxygen, and O_{H} indicates the amount of H₂O, CO₃, O₂ adsorbed to the surface, as shown in FIG. 36 to FIG. 39. When concentration of yttrium is 0%, O_{M}/O_{L} is 35.4%. When concentration of yttrium is 6%, O_{M}/O_{L} is 31.7%. When concentration of yttrium is 12%, O_{M}/O_{L} reduces to 20.2%. When concentration of yttrium is 20%, O_{M}/O_{L} further decreases to 18.4%, which is the lowest. A trend is obviously observed that with increasing doping concentration of yttrium into the indium oxide, the amount of bonding between the indium to oxygen increases, hence, the oxygen vacancies decrease.

The results prove that because the electronegativity difference between Y/O is larger than the electronegativity difference between In/O, doping yttrium into the indium oxide effectively binds oxygen, thus suppressing the formation of oxygen vacancies and decreasing the carrier concentration.

As mentioned above, Sol-gel process is successfully used to fabricate a transistor with a yttrium-doped indium oxide transparent conductive thin-film in the present invention. Through analyses by varied instruments, the present invention is a contributive breakthrough to the prior art. The binding capacity of yttrium to oxygen of YIO thin film is increased through doping yttrium. After YIO thin film is sintered under atmosphere at a high temperature, the YIO thin film reduces the formation of oxygen vacancies, suppresses carrier concentration effectively, and decreases maximum defect density, so the YIO thin film of the present invention is successfully applied to the transistors.

The transistor exhibits no transistor characteristics when the doping concentration of yttrium is 0%. The transistor exhibits high mobility but the channel is not fully pinched-off and the S.S value cannot be decreased due to the high maximum defect density when the doping concentration of yttrium is 6%. When the doping concentration of yttrium is 12%, the on/off ratio is 2.12×10⁵, the Vₜₕ is 6.69V and the mobility is 1.43, and the transistor is effectively applied to the transistors. Although the transistor with the doping concentration of yttrium of 20% has a higher on/off ratio, namely, lower maximum defect density, the transistor lacks carrier transmission and the mobility is too low because the doping concentration of yttrium is too high. In conclusion, the transistor with the concentration of yttrium of 12% exhibits the best properties.

Even though numerous characteristics and advantages of the present invention have been set forth in the foregoing description, together with details of the structure and features of the invention, the disclosure is illustrative only. Changes may be made in the details, especially in changing atmosphere and temperature to change properties of transistors, lowering temperature to fabricate flexible substrates and arrangement of parts within the principles of the invention to the full extent indicated by the broad general meaning of the terms in which the appended claims are expressed.

What is claimed is:

1. A thin film transistor device comprising:
a P-type silica substrate;
a silicon substrate formed on one surface of the P-type silica substrate;
an yttrium-doped indium oxide thin film as an active layer formed on the silicon substrate, wherein the doping ratio of yttrium is 12% to 20%; and
two electrodes formed on the yttrium-doped indium oxide thin film.

2. The thin film transistor device according to claim 1, wherein the thin film transistor device has a channel length of 1000 μm and a channel width of 100 μm, and wherein the thickness of yttrium-doped indium oxide thin film is about 40 nm.

3. The thin film transistor device according to claim 2, wherein the P-type silica substrate has a electrical resistivity of 0.001-0.025Ω, and the thickness of the silicon substrate formed on one surface of the P-type silica substrate is 80 nm.

4. The thin film transistor device according to claim 3, wherein the two electrodes are aluminum electrodes.

5. The thin film transistor device according to claim 4, wherein the yttrium-doped indium oxide thin film is with a doping ratio of yttrium of 12%.

6. A method for making a thin film transistor device comprising steps of:
preparing a P-type silica substrate and a silicon substrate formed on one surface of the P-type silica substrate;
washing the P-type silica substrate and the silicon substrate;
forming an yttrium-doped indium oxide thin film on the silicon substrate, wherein the doping ratio of yttrium is 12% to 20%;
forming two electrodes on the yttrium-doped indium oxide thin film; and
defining an active layer on the yttrium-doped indium oxide thin film.

7. The method for making a thin film transistor device according to claim 6, wherein the yttrium-doped indium oxide thin film is fabricated by sol-gel process.

8. The method for making a thin film transistor device according to claim 7, wherein the active layer is fabricated by sequentially coating photo resist on the yttrium-doped indium oxide thin film, defining the position of the active layer by mask aligner and etching with hydrofluoric acid solution.

9. The method for making a thin film transistor device according to claim 8, wherein after defining an active layer on the yttrium-doped indium oxide thin film, a gate is formed on the yttrium-doped indium oxide thin film by etching.

10. The method for making a thin film transistor device according to claim 9, wherein the yttrium-doped indium oxide thin film is with a doping ratio of yttrium of 12%.
